(19) United States
(12) Patent Application Publication
(10) Pub. No.: US 2025/0269408 A1
(43) Pub. Date: Aug. 28, 2025

(54) CLEANING APPARATUS AND CLEANING METHOD

(71) Applicant: DISCO CORPORATION, Tokyo (JP)

(72) Inventor: Dai SAITO, Tokyo (JP)

(73) Assignee: DISCO CORPORATION, Tokyo (JP)

(21) Appl. No.: 19/051,429

(22) Filed: Feb. 12, 2025

(30) Foreign Application Priority Data
Feb. 26, 2024 (JP) 2024-026233

(51) Int. Cl. B08B 3/02

(52) U.S. Cl. CPC B08B 3/02; B08B 2203/0211

(57) ABSTRACT

A cleaning apparatus including a cleaning unit configured to clean a cleaning object includes a supporting portion, which is located on a side of a first surface of the cleaning object and is configured to support the cleaning object; and at least one first supply port, from which a rotational fluid is supplied to the cleaning object supported by the supporting portion. The cleaning apparatus is configured to clean the cleaning object while the cleaning object is rotated by the rotational fluid supplied from the at least one first supply port.

### CROSS REFERENCE TO RELATED APPLICATION

This application is based upon and claims the benefit of priority from the prior Japanese Patent Application No. 2024-026233 filed on Feb. 26, 2024; the entire contents of which are incorporated herein by reference.

### FIELD

The present disclosure relates to a cleaning apparatus and a method for cleaning a cleaning object.

### BACKGROUND

A processing apparatus for processing workpieces may clean the workpieces before and after the processing. For example, when manufacturing semiconductor devices, each workpiece such as a wafer may be processed through grinding, polishing, cutting, and laser irradiation, and the processed workpiece may be conveyed to a cleaning apparatus (a cleaning unit provided to the processing apparatus) and cleaned thereat to remove swarf that adhered thereto during the processing. Hereinbelow, a workpiece being an object to be cleaned by the cleaning apparatus may be called a cleaning object.

In order to efficiently clean the entire cleaning object, for example, Japanese Patent Laid-Open Publication No. 2015-041653 discloses a spinner-styled cleaning apparatus, in which a cleaning object is supported rotatably by a spinner and cleaned while being rotated.

### SUMMARY

The spinner-styled cleaning apparatus may easily clean the entire cleaning object without operating cleaning devices (such as cleaning nozzles, cleaning brushes, etc.) complicatedly. On the other hand, for cleaning the cleaning object while the cleaning object is supported on a supporting surface and being rotated, the cleaning apparatus may require a rotating mechanism, including a motor to rotate the supporting surface and a transmission. As such, downsizing of the cleaning apparatus may be restricted by the rotating mechanism.

The present disclosure is directed to providing a cleaning apparatus and a cleaning method, which enable a cleaning object to be cleaned efficiently in a downsized structure.

According to an aspect of the present disclosure, a cleaning apparatus including a cleaning unit configured to clean a cleaning object includes a supporting portion, which is located on a side of a first surface of the cleaning object and is configured to support the cleaning object; and at least one first supply port, from which a rotational fluid is supplied to the cleaning object supported by the supporting portion. The cleaning apparatus is configured to clean the cleaning object while the cleaning object is rotated by the rotational fluid supplied from the at least one first supply port.

Optionally, the supporting portion may be configured to support an outer edge of the cleaning object and include a side portion configured to cover an exterior of the cleaning object supported by the supporting portion. Moreover, optionally, the at least one first supply port may be formed on an inner circumference of the side portion.

Optionally, the cleaning apparatus may further include at least one second supply port provided on a supporting surface, which is a surface of the supporting portion configured to support the cleaning object thereon. The cleaning unit may be configured to clean the cleaning object in a state where the cleaning object is elevated from the supporting surface by a floater fluid supplied from the at least one second supply port.

Optionally, the cleaning unit may be configured to clean at least one of the first surface, a second surface opposite to the first surface, or a side surface, of the cleaning object. Moreover, optionally, the cleaning unit may at least include the at least one first supply port and may be configured to clean the cleaning object with the rotational fluid. Moreover, optionally, the cleaning unit may include, separately from the at least one first supply port, a cleaning device that may be located at a position to face at least one of the first surface of the cleaning object supported by the supporting portion or a second surface opposite to the first surface of the cleaning object, and the cleaning unit may be configured to clean the cleaning object using the cleaning device.

Optionally, the cleaning apparatus further includes a lid configured to be arranged to face a second surface opposite to the first surface of the cleaning object. Moreover, optionally, the cleaning apparatus may further include at least one third supply port, through which a fluid is supplied to the cleaning object, on a surface of the lid that faces the cleaning object.

According to another aspect of the present disclosure, a method for cleaning the cleaning object in the cleaning apparatus includes a supporting step, including supporting the cleaning object with the supporting portion; a rotating step, including supplying the rotational fluid from the at least one first supply port to the cleaning object and causing the cleaning object supported by the supporting portion to rotate; and a cleaning step, including cleaning the cleaning object while the cleaning object rotates.

According to the above cleaning apparatus and the cleaning method, the cleaning object may be rotated by the rotational fluid supplied from the first supply port and may be cleaned while being rotated, thereby enabling cleaning of the cleaning object efficiently in a downsized structure.

### BRIEF DESCRIPTION OF THE DRAWINGS

FIG. 1 is a perspective view of supporting units composing a cleaning apparatus according to a first embodiment.

FIG. 2 is a perspective view of the supporting units supporting a cleaning object in the cleaning apparatus according to the first embodiment.

FIG. 3 is a cross-sectional view of the supporting units supporting the cleaning object in the cleaning apparatus according to the first embodiment.

FIG. 4 is a plan view of the cleaning apparatus according to the first embodiment.

FIG. 5 is a part of a flowchart to illustrate a flow of processes to be performed in the cleaning apparatus according to the first embodiment.

FIG. 6 is another part of the flowchart to illustrate the flow of the processes to be performed in the cleaning apparatus according to the first embodiment.

FIG. 7 is a perspective view of supporting units composing a cleaning apparatus according to a second embodiment.

FIG. 8 is a cross-sectional view of the supporting units supporting the cleaning object in the cleaning apparatus according to the second embodiment.

FIG. 9 is a cross-sectional view of supporting units supporting the cleaning object in a cleaning apparatus according to a third embodiment.

FIG. 10 is a plan view of the cleaning apparatus according to the third embodiment.

FIG. 11 is a cross-sectional view of supporting units supporting the cleaning object in a cleaning apparatus according to a fourth embodiment.

FIG. 12 is a plan view of a cleaning apparatus according to a fifth embodiment.

FIG. 13 is a cross-sectional view sectioned along a line A-A indicated in FIG. 12.

FIG. 14 is a cross-sectional view of a cleaning apparatus according to a sixth embodiment.

FIG. 15 is a plan view of the cleaning apparatus according to the sixth embodiment.

### DESCRIPTION OF EMBODIMENTS

With reference to the accompanying drawings, cleaning apparatuses according to embodiments of the present disclosure and a cleaning method using the cleaning apparatuses according to the embodiments will be described. The cleaning apparatus in each embodiment may clean a disk-shaped cleaning object S. The cleaning apparatus may either be provided as part of a processing apparatus that may process the cleaning object S or may be an apparatus independent from the processing apparatus. The cleaning apparatus may clean a cleaning object S having been processed by the processing apparatus, a cleaning object S before processing, or a cleaning object S before and/or after another fabrication that does not involve processing (inspection, applying or removal of a tape, image-capturing, etc.). The cleaning object S may be, for example, a semiconductor wafer, a package substrate, or an optical device wafer, but the material or the type of the cleaning object S is not limited.

A Z-axis direction in each of the drawings illustrating the embodiments is a vertical direction of the cleaning apparatus, where a +Z direction side is upward and a −Z direction side is downward. The Z-axis direction is also a thickness direction of the cleaning object S when the cleaning object S is being cleaned in the cleaning apparatus. The cleaning apparatus in each embodiment may, when cleaning the cleaning object S, supply a rotational fluid to the cleaning object S and cause the cleaning object S to rotate by a force of the rotational fluid. In the cleaning apparatus in each embodiment, a direction in which the cleaning object S rotates will be called a rotating direction. The cleaning object S may rotate along a horizontal plane, which is substantially orthogonal to the Z-axis direction.

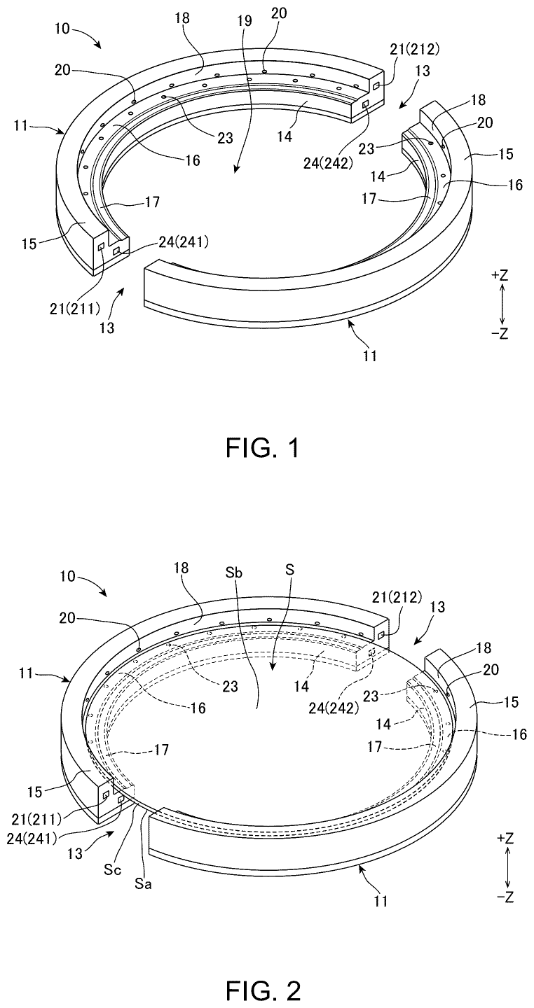

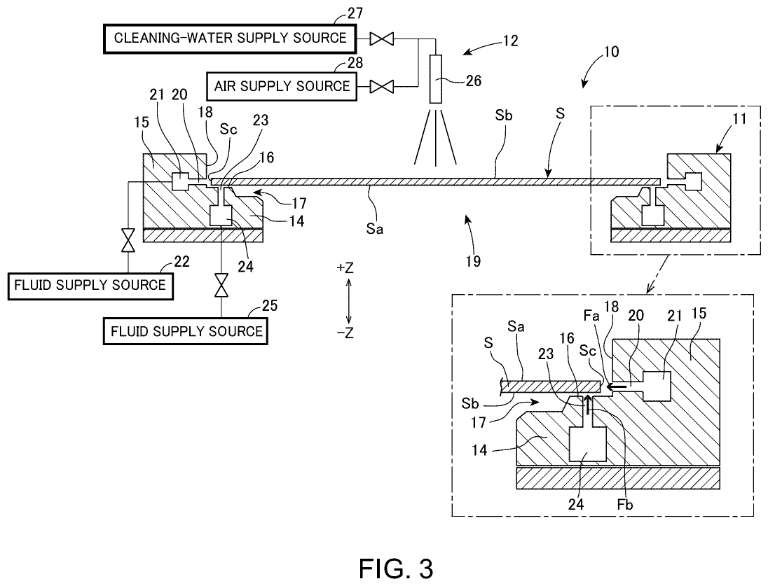

FIGS. 1 through 4 illustrate a cleaning apparatus 10 according to a first embodiment. The cleaning apparatus 10 includes supporting units 11 to support the cleaning object S and a cleaning unit 12 (see FIG. 3) to clean the cleaning object S supported by the supporting units 11. The cleaning object S has a first surface Sa, by which the cleaning object S is supported on the supporting units 11, a second surface Sb on a side opposite to the first surface Sa, and a side surface Sc connecting the first surface Sa and the second surface Sb on an outer circumference. When the cleaning object S is supported on the supporting units 11, the first surface Sa is on a lower side, and the second surface Sb is on an upper side.

The supporting units 11 form a ring to support an outer edge of the cleaning object S. The supporting units 11 include an opening portion 19 at a center thereof formed there-through in the vertical direction, and a central portion of the cleaning object S is not directly supported by the supporting units 11. For example, when the cleaning object S is a semiconductor wafer or an optical device wafer, a central portion of the cleaning object S, on which a device may be formed, is located to coincide with the opening portion 19 in the supporting units 11 so that merely the outer edge of the cleaning object S is supported by the supporting units 11.

At positions on the circumference of the supporting units 11, communicating portions 13 are formed. Two communicating portions 13 are located substantially symmetrically across the center of the ring-shaped supporting units 11. The communicating portions 13 are each formed as a space to connect the opening portion 19 on an inner side and an outer side of the supporting units 11 in a radial direction. A main function of the communicating portions 13 is to discharge fluid that may flow in the opening portion 19 to the outside of the supporting units 11; therefore, the configuration of the communicating portions 13 may not necessarily be limited as long as the discharging function is ensured.

For example, FIGS. 1 and 2 show the supporting units 11, which are provided in two pieces separated completely by the two communicating portions 13 in the circumferential direction, but optionally, a member in an integrally formed structure, which is continuous in the communicating portions 13 at least partly in the circumferential direction, may compose a supporting unit 11.

Each supporting unit 11 includes a supporting portion 14 and a side portion 15, which are formed integrally. The supporting portions 14 in the supporting units 11 form a ring located on the inner circumferential side of the supporting units 11, and a thickness thereof in the vertical direction is smaller than the side portions 15. Each supporting portion 14 has a supporting surface 16, which is a flat annular surface facing upward. Moreover, on the inner circumferential side of the supporting surface 16, a discharging portion 17 in a stepped shape is formed to be lower than the supporting surface 16. The part of the supporting units 11 on the inner circumferential side of the supporting portions 14 forms the opening portion 19, which is open in the vertical direction. The discharging portions 17 are not required but may be omitted optionally.

The side portions 15 form a ring located on the outer circumferential side of the supporting units 11. A thickness thereof of the side portions 15 in the vertical direction is greater than the supporting portions 14 so that the side portions 15 protrude to be higher than the supporting surfaces 16. The side portions 15 have cylindrically-formed inner circumferential surfaces 18 extending upward from outer edges of the supporting surfaces 16.

As shown in FIGS. 2 and 3, the cleaning object S conveyed to the cleaning apparatus 10 is supported by the supporting units 11. In particular, the cleaning object S is supported on the annular step formed of the supporting surfaces 16 of the supporting portions 14 and the inner circumferential surfaces 18 of the side portions 15. The supporting portions 14 are located on a side of the first surface Sa of the cleaning object S, and the annular supporting surfaces 16 may support the outer edge (an area on the first surface Sa closer to the side surface Sc) of the cleaning object S. The side portions 15 are located to cover an exterior of the side surface Sc of the cleaning object S Sc of the cleaning object S, and the inner circumferential surfaces 18 in the cylindrical form, of which inner diameter is greater than a diameter of the cleaning object S, faces the side surface Sc.

The side portions 15 each have a plurality of first supply ports 20 formed to open on the inner circumferential surfaces 18. The plurality of first supply ports 20 are located at predetermined intervals along the circumferential direction of the supporting units 11 (in the rotating direction of the cleaning object S). The plurality of first supply ports 20 are located at a position in the vertical direction on the inner circumferential surfaces 18 toward the supporting surfaces 16 closer to a lower end of the inner circumferential surfaces 18. The plurality of first supply ports 20 arranged in this manner are located to face the side surface Sc of the cleaning object S supported by the supporting units 11.

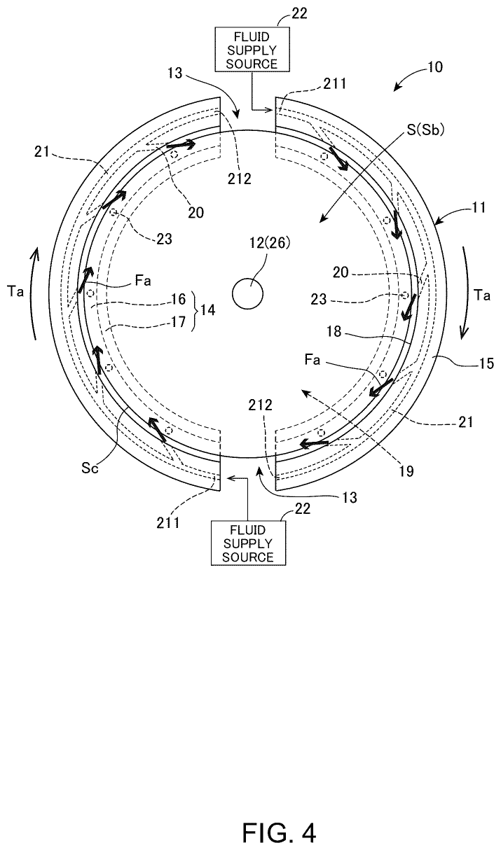

As shown in FIGS. 3 and 4, inside each supporting unit 11, a fluid supply path 21 extending in the circumferential direction is provided. The fluid supply path 21 is a flow path located annularly on the outer side of the inner circumferential surface 18 and is formed in a shape of an arc with a curvature radius being greater than a curvature radius of the inner circumferential surface 18. The plurality of first supply ports 20 are formed as flow paths branching off from the fluid supply path 21 and extending to the inner circumferential surface 18. As shown in FIG. 4, each first supply port 20 has a form, in a plan view, that changes circumferential position thereof as it extends away from the fluid supply path 21 and approach the inner circumferential surface 18. In other words, the first supply ports 20 each have a flow path in a shape including a component of the rotating direction of the cleaning object S supported by the supporting units 11 (which is non-parallel to the radial direction of the cleaning object S).

The cleaning apparatus 10 is provided with a fluid supply source 22, which may supply fluid to the fluid supply paths 21 and is connected to the fluid supply paths 21 through an open/close valve. The fluid supply source 22 includes a tank to store the fluid and a pump to pump the fluid from the tank. The fluid to be supplied by the fluid supply source 22 is at least one of a liquid, such as pure water, pure water containing agents such as surfactants, or a mixture of two fluids containing air and water, or a gas such as air. In consideration of ease of availability, operating cost, and environment impact after use, it is preferable that the fluid to be supplied by the fluid supply source 22 may be water or air. In a case where the cleaning object S is made of a material or is of a type that is inappropriate to be exposed to water or air, a fluid other than water or air may supplied from the fluid supply source 22.

In a case where the fluid supply source 22 is capable of supplying both a liquid and a gas, the fluid supply source 22 may be configured to have a liquid supply source and a gas supply source, and the type of the fluid to be supplied to the fluid supply paths 21 may be selected by an operation of an open/close valve in a flow path connecting to the liquid supply source and the gas supply source. Optionally, a mixed fluid (two fluids) containing both a liquid and a gas may be supplied from the fluid supply source 22.

On one of end faces of each supporting unit 11 in the circumferential direction facing the communicating portion 13, an inlet 211, from which the fluid supplied from the fluid supply source 22 may be drawn into the fluid supply path 21, is formed, and on the other of the end faces of each supporting unit 11 in the circumferential direction facing the communicating portion 13, an outlet 212, from which the fluid flowed through the fluid supply path 21 may be discharged, is formed.

The fluid supplied from the fluid supply source 22 to the inlet 211 of each fluid supply path 21 may travel in a flowing direction Ta (see FIG. 4) inside the fluid supply path 21 in the arc shape in the plan view. The plurality of first supply ports 20 are formed at points to branch from the fluid supply path 21 in an orientation that forms an acute angle with a tangent line of the flowing direction Ta, so that the fluid flowing through the inside of the fluid supply path 21 may easily enter the individual first supply ports 20. The fluid entering the first supply ports 20 may be jetted out from outlets of the first supply ports 20 formed on the inner circumferential surface 18.

The fluid jetted from the first supply ports 20 will be herein called a rotational fluid Fa. In FIGS. 3 and 4, the rotational fluid Fa is represented schematically in arrows. The rotational fluid Fa jetted along the shape of the first supply port 20 is oriented in a direction including a component of the rotating direction of the cleaning object S. In particular, the rotating direction of the cleaning object S is substantially the same as the flowing direction Ta of the fluid flowing along the fluid supply path 21. The orientation of the rotational fluid Fa is a composite of a component along the flowing direction Ta and a radial component of the direction from the fluid supply path 21 toward the center (toward the opening portion 19) of the supporting units 11. Accordingly, the rotational fluid Fa flows, in a plan view, in the rotating direction of the cleaning object S while skewing toward the center of the supporting units 11.

The rotational fluid Fa jetted from the first supply ports 20 may hit the side surface Sc of the cleaning object S that faces the first supply ports 20 and the outer edges of the first surface Sa and the second surface Sb adjacent to the side surface Sc, thereby applying a force in the rotating direction to the cleaning object S. As a result, the cleaning object S supported by the supporting units 11 may be rotated by the force of the rotational fluid Fa.

The plurality of first supply ports 20 are provided at the predetermined intervals in the rotating direction (circumferential direction of the supporting units 11) on the side portions 15 covering the exterior of the cleaning object S supported by the supporting portions 14. With this configuration, when the rotational fluid Fa is jetted from the plurality of first supply ports 20, the rotational fluid Fa may apply the force in the rotating direction and the force to push toward the center of the radial direction to the cleaning object S. Accordingly, the cleaning object S may be rotated while the position of the cleaning object S in the horizontal direction is stabilized.

As such, the rotational fluid Fa jetted from the first supply ports 20 may hit the areas in the vicinity of the outer edge of the cleaning object S and cause the cleaning object S to rotate. A flowing speed and a flowing amount of the rotational fluid Fa may be set according to a pressure and amount of the fluid supplied from the fluid supply source 22. Therefore, with a controller (not shown) in the cleaning apparatus 10 controlling behaviors of the fluid supply source 22, a rotational speed of the cleaning object S may be set preferably.

Meanwhile, behaviors of the cleaning apparatus 10 may, as described further below, differ depending on the type of the fluid supplied from the fluid supply source 22. For example, in a case where the rotational fluid Fa is also used as cleaning water in a cleaning sequence described below, the fluid supply source 22 may be configured to be capable of supplying the fluid that functions as the cleaning water. For another example, when the cleaning apparatus 10 conducts a drying sequence, which will be described further below, the fluid supply source 22 may be configured to be capable of supplying at least a gas so as not to hinder the cleaning object S from drying.

Moreover, the rotational fluid Fa, when it is liquid rather than gas, is more viscous, and it is easier to apply the rotational force to the cleaning object S. Therefore, a liquid and a gas may be used occasionally according to the rotational force required to the rotational fluid Fa.

Note that, in the configuration shown in the drawings, the inlet 211 for introducing the fluid supplied from the fluid supply source 22 into the fluid supply path 21 and the outlet 212 for discharging the fluid from the fluid supply path 21 are formed on one and the other end faces of each supporting unit 11, respectively, in the circumferential direction facing the communicating portion 13; however, the configuration of the inlet and the outlet of the fluid supply path 21 is not necessarily limited. For example, the inlet and/or the outlet of the fluid supply path 21 may be provided on an outer circumferential surface, an inner circumferential surface, an upper surface, or a lower surface of the supporting unit 11. For another example, the fluid supply path 21 may have only the first supply ports 20 as the exit of the fluid from the fluid supply path 21 (where no other outlet than the first supply ports 20 is provided in the fluid supply path 21) so that all of the fluid that flows through the fluid supply path 21 may be jetted from the openings of the fluid supply path 21.

As described above, the cleaning apparatus 10 does not rotate the supporting units 11 but rotates the cleaning object S with the rotational fluid Fa supplied through the supporting units 11. Therefore, a rotating mechanism to rotate the supporting units 11 is not required, and the cleaning apparatus 10 may be provided in a compact and simple structure.

The supporting portion 14 in each supporting unit 11 has a plurality of second supply ports 23 that are open on the supporting surface 16. The plurality of second supply ports 23 are provided at predetermined intervals in the circumferential direction of the supporting units 11 (in the rotating direction of the cleaning object S). The plurality of second supply ports 23 in this arrangement are located to face the first surface Sa in the vicinity of the outer edge of the cleaning object S supported by the supporting units 11.

As shown in FIG. 3, inside each supporting unit 11, a fluid supply path 24 extending in the circumferential direction is formed. The fluid supply path 24 forms an annular flow path located on the inner side in the circumferential direction with respect to the inner circumferential surface 18 of the side portion 15, having an arc form, of which curvature radius is smaller than the curvature radius of the fluid supply path 21. The plurality of second supply ports 23 are formed to branch off from the fluid supply path 24 and extend to the supporting surface 16. As shown in FIG. 3, the second supply ports 23 extend substantially vertically.

The cleaning apparatus 10 is provided with a fluid supply source 25 to supply the fluid to the fluid supply paths 24 and is connected to the fluid supply paths 24 via an open/close valve. The fluid supply source 25 includes a tank to store the fluid and a pump to pump the fluid from the tank. The fluid to be supplied by the fluid supply source 25 is at least one of a liquid or a gas, preferably water, when the fluid is a liquid, or air, when the fluid is a gas. Optionally, depending on the material or the type of the cleaning object S, a fluid other than water or air may supplied from the fluid supply source 25.

In a case where the fluid supply source 25 is capable of supplying both a liquid and a gas, the fluid supply source 25 may be configured to have a liquid supply source and a gas supply source, and the type of the fluid to be supplied to the fluid supply paths 24 may be selected by an operation of an open/close valve in a flow path connecting to the liquid supply source and the gas supply source. Optionally, a mixed fluid (two fluids) containing both a liquid and a gas may be supplied from the fluid supply source 25.

On one of the end faces of each supporting unit 11 in the circumferential direction facing the communicating portion 13, an inlet 241, from which the fluid supplied from the fluid supply source 25 may be drawn into the fluid supply path 24, is formed, and on the other of the end faces of each supporting unit 11 in the circumferential direction facing the communicating portion 13, an outlet 242, from which the fluid flowed through the fluid supply path 24 may be discharged, is formed.

The fluid supplied from the fluid supply source 25 to the inlet 241 of each fluid supply paths 24 may travel inside the fluid supply path 24 in the arc shape in the plan view. The fluid flowing through the fluid supply paths 24 may enter the individual second supply ports 23 and may be jetted out from outlets of the second supply ports 23 formed on the supporting surface 16.

The fluid jetted from the second supply ports 23 will be herein called a floater fluid Fb. In FIG. 3, the floater fluid Fb is represented schematically in an arrow. The floater fluid Fb jetted from the second supply ports 23, which extend in the vertical direction, flows upward from the supporting surfaces 16 and hits the first surface Sa of the cleaning object S, applying a force to elevate the cleaning object S. The force of the floater fluid Fb may elevate the cleaning object S from the supporting surfaces 16 and cause the cleaning object S to rotate without contacting the supporting surfaces 16.

When the cleaning object S is elevated by the floater fluid Fb and shifts to a state not contacting the supporting surface 16, a frictional resistance is reduced compared to the case where the first surface Sa of the cleaning object S is in contact with the supporting surfaces 16, and the cleaning object S may be rotated at a high speed by a low load. Moreover, the higher rotation speed of the cleaning object S during cleaning may improve the cleaning effect. When the frictional resistance against the rotation of the cleaning object S is smaller, the cleaning object S may be rotated efficiently with a relatively small amount of flow of the rotational fluid Fa, and power consumption by the pump of the fluid supply source 22 for supplying the rotational fluid Fa may be reduced.

Moreover, in the arrangement where the cleaning object S is elevated by the floater fluid Fb and shifted to the state not contacting the supporting surface 16, the rotating cleaning object S may be prevented from contact with the supporting surfaces 16 by the outer edge thereof and may be prevented from being dirtied or damaged by the supporting surfaces 16.

Therefore, by supplying the floater fluid Fb to elevate the cleaning object S, combined effects, such as improving the rotational efficiency of the cleaning object S, improving the cleaning effect by high-speed rotation of the cleaning object S, and preventing stains or damages on the outer edge of the cleaning object S, may be achieved.

The flowing speed and the flowing rate of the floater fluid Fb are set depending on the pressure or the amount of the fluid to be supplied from the fluid supply source 25. Therefore, by the controller controlling the cleaning apparatus 10 and the behavior of the fluid supply source 25, an amount of floatation of the cleaning object S may be varied preferably.

The behaviors of the cleaning apparatus 10, as will be described further below, may differ depending on the type of the fluid that may be supplied from the fluid supply source 25. For example, in a case where the floater fluid Fb is also used as cleaning water in a cleaning sequence described below, the fluid supply source 25 may be configured to be capable of supplying a fluid that functions as the cleaning water. For another example, when the cleaning apparatus 10 conducts a drying sequence, which will be described further below, the fluid supply source 25 may be configured to be capable of supplying at least a gas so as not to hinder the cleaning object S from drying.

Note that, in the configuration shown in the drawings, the inlet 241 for introducing the fluid supplied from the fluid supply source 25 into the fluid supply path 24 and the outlet 242 for discharging the fluid from the fluid supply path 24 are formed on one and the other end faces of each supporting unit 11, respectively, in the circumferential direction facing the communicating portion 13; however, the configuration of the inlet and the outlet of the fluid supply path 24 is not necessarily limited. For example, the inlet and/or the outlet of the fluid supply path 24 may be provided on an outer circumferential surface, an inner circumferential surface, an upper surface, or a lower surface of the supporting unit 11. For another example, the fluid supply path 24 may have only the second supply ports 23 as the exit of the fluid in the fluid supply path 24 (where no other outlet than the second supply ports 23 is provided in the fluid supply path 24) so that all of the fluid that flows through the fluid supply path 24 may be jetted from the fluid supply path 24.

The supporting units 11 are the paired parts forming a ring divided in half in the circumferential direction at the pair of communicating portions 13, each having a configuration for supplying the rotational fluid Fa through the first supply ports 20 to the cleaning object S and a configuration for supplying the floater fluid Fb to the cleaning object S through the second supply ports 23. Although FIG. 4 shows two separate fluid supply sources 22 for ease of illustration, the actual configuration of the apparatus requires at least one fluid supply source 22 and one fluid supply source 25. Optionally, a single fluid supply source may be configured to double as the fluid supply source 22 and the fluid supply source 25. In this arrangement, supplying of the fluid from the same fluid supply source to the fluid supply path 21 or the fluid supply path 24 may be managed through, for example, individual open/close valves.

As shown in FIG. 3, the rotational fluid Fa and the floater fluid Fb are supplied to the areas in the vicinity of the outer edge of the cleaning object S covered by the side portions 15. In particular, the rotational fluid Fa is supplied to the area in the vicinity of the side surface Sc of the cleaning object S, and the floater fluid Fb is supplied to the area in the vicinity of the first surface Sa, closer to the side surface Sc of the cleaning object S. If, for example, the rotational fluid Fa or the floater fluid Fb stays accumulatively in the area near the outer edge of the cleaning object S, the posture and the rotation of the cleaning object S tend to become unstable due to the accumulation of the fluid. This tendency may be particularly strong in a case where the rotational fluid Fa or the floater fluid Fb is liquid, of which viscosity is higher than a gas.

Each supporting unit 11 has a discharging portion 17, which forms a larger gap with the cleaning object S than with the supporting surface 16, at an inward and adjacent position with respect to the supporting surface 16. With this arrangement, the rotational fluid Fa and the floater fluid Fb supplied to the areas in the vicinity of the outer edge of the cleaning object S may be easily discharged toward the opening portion 19 on the inner circumferential side of the supporting units 11 through the discharging portions 17. Moreover, the rotational fluid Fa and the floater fluid Fb entering the opening portion 19 may be discharged outside the supporting units 11 through the communicating portions 13, at which the opening portion 19 and the outside of the supporting units 11 communicate. As such, the rotational fluid Fa and the floater fluid Fb may be prevented from remaining in the areas in the vicinity of the outer edge of the cleaning object S, and the cleaning object S may be stabilized in the posture and rotated accurately.

As shown in FIG. 3, the cleaning unit 12 includes a cleaning nozzle 26 located above the supporting units 11. A cleaning-water supply source 27 and an air supply source 28 are connected to the cleaning nozzle 26 via respective open/close valves. The cleaning nozzle 26 may jet cleaning water supplied from the cleaning-water supply source 27, air supplied from the air supply source 28, or a mixed fluid containing cleaning water and air (two fluids) downward. The cleaning nozzle 26 is a cleaning device that may be located at a position to face the second surface Sb of the cleaning object S which is supported by the supporting units 11, and when the cleaning object S is supported by the supporting units 11, cleaning water, air, or mixed fluid (two fluids) may be jetted from the cleaning nozzle 26 at the second surface Sb of the cleaning object S, and the cleaning object S may be cleaned with the fluid jetted from the cleaning nozzle 26.

The cleaning nozzle 26 is movable in the radial direction of the cleaning object S with a nozzle-driving assembly, which is not shown. By moving the cleaning nozzle 26 in the radial direction of the cleaning object S while rotating the cleaning object S by the effect of the rotational fluid Fa, the fluid, such as cleaning water, air, or mixed fluid (two fluids), jetted from the cleaning nozzle 26 may be delivered to the entire second surface Sb of the cleaning object S.

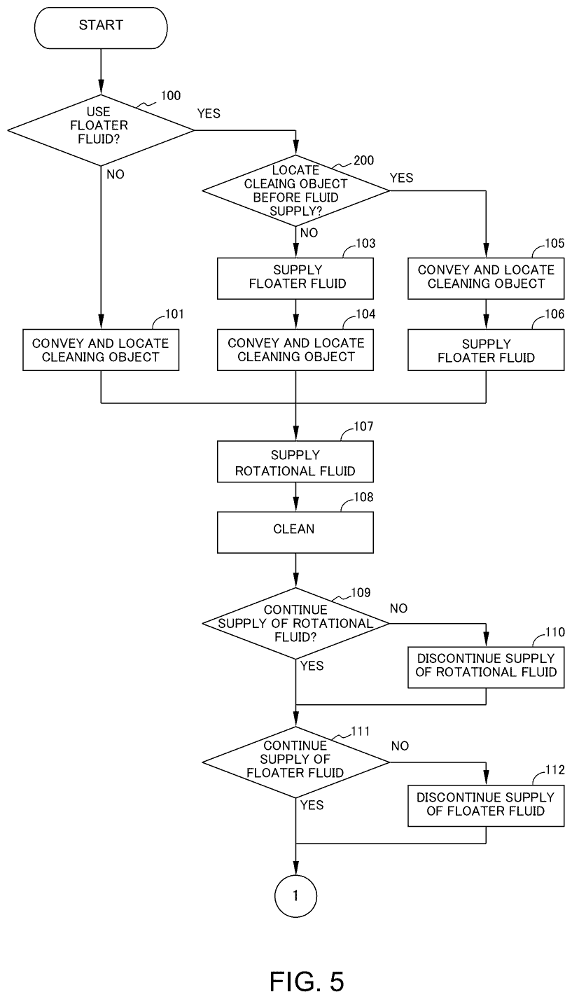

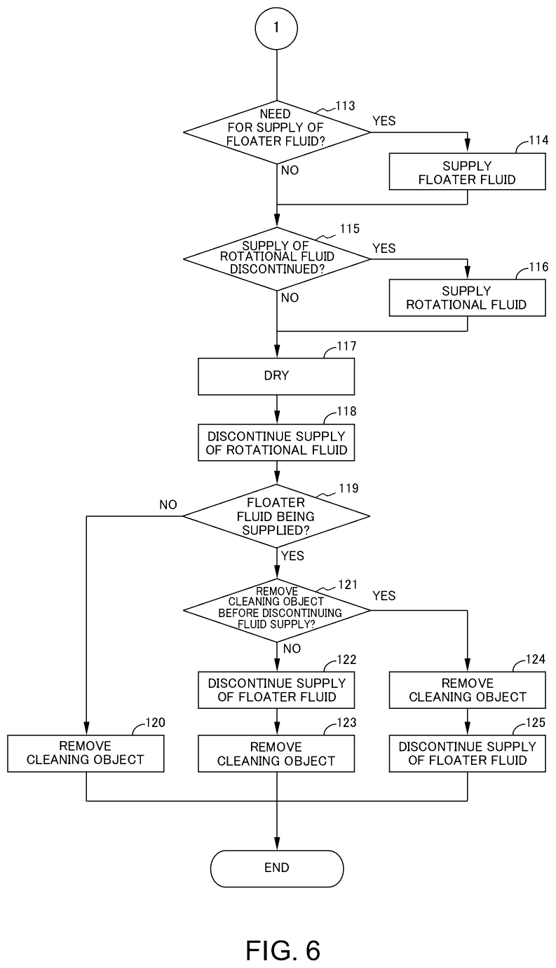

Cleaning operations and a method performed with the cleaning apparatus 10 configured as above will be described below. The cleaning operations with the cleaning apparatus 10 to the cleaning object S includes the cleaning sequence shown in the flowchart in FIG. 5 and the drying sequence shown in the flowchart in FIG. 6, where the cleaning sequence and drying sequence are performed continuously. The cleaning apparatus 10 includes the controller, which may control operations and processes in the cleaning sequence and the drying sequence. In the present embodiment, the controller automatically determines a condition and selects a step to proceed at each point where the flow branches in the cleaning sequence and the drying sequence; however, the selection may be made manually by an operator of the cleaning apparatus 10 who determines the condition.

### Cleaning Sequence

In the cleaning sequence, the cleaning apparatus 10 may select an option for cleaning between cleaning the cleaning object S in a state elevated by the floater fluid Fb and cleaning the cleaning object S in a state not being elevated by the floater fluid Fb. Cleaning the cleaning object S in the state not being elevated by the floater fluid Fb is performed by rotating the cleaning object S in a state where the outer edge of the first surface Sa is in contact with the supporting surfaces 16 of the supporting units 11. As described above, it is preferable that the floater fluid Fb is supplied to the cleaning object S when the cleaning object S is being rotated; however, an option not to supply the floater fluid Fb to the cleaning object S may be available when, for example, frictional resistance between the cleaning object S and the supporting units 11 is small even without the floater fluid Fb.

In Step 100, the controller determines an operating condition of the cleaning apparatus 10 in the cleaning sequence. If the operating condition meets the condition for cleaning without using the floater fluid Fb (NO in Step 100), the control proceeds to Step 101. In Step 101, the cleaning object S is conveyed to the supporting units 11 and placed on the supporting surfaces 16 by the conveyer assembly (not shown) without having the floater fluid Fb supplied from the second supply ports 23. The conveyed cleaning object S is supported on the supporting surfaces 16 by the outer edge of the first surface Sa.

Optionally, unlike the cleaning apparatus 10 in the present embodiment, a cleaning apparatus not equipped with the function to supply the floater fluid Fb to the cleaning object S may be provided. In this configuration, the control always makes a negative determination NO in Step 100.

If the operating condition meets the condition for cleaning with use of the floater fluid Fb (YES in Step 100), the control proceeds to Step 102, where the controller determines a setting of timing when the cleaning object S is to be supported by the supporting units 11.

In a case where the cleaning object S is to be supported by the supporting units 11 after supplying the floater fluid Fb (NO in Step 102), the control proceeds to Step 103, where the floater fluid Fb is supplied from the second supply ports 23, and thereafter to Step 104, where the cleaning object S is conveyed by the conveyer assembly to the supporting units 11 and placed on the supporting surfaces 16.

In a case where the cleaning object S is to be supported by the supporting units 11 before supplying the floater fluid Fb to the cleaning object S (YES in Step 102), the control proceeds to Step 105, where the cleaning object S is conveyed by the conveyer assembly to the supporting units 11 and placed on the supporting surfaces 16, and thereafter to Step 106, where the floater fluid Fb is supplied from the second supply ports 23 to the cleaning object S.

It is preferable that a liquid is the floater fluid Fb to be supplied in Step 103 and Step 106. If a gas as the floater fluid Fb is supplied for cleaning, the cleaning object S may dry in the vicinity of the area where the cleaning object S is exposed to the jetted floater fluid Fb, causing foreign matter to adhere to the cleaning object S. By using a liquid as the floater fluid Fb, the cleaning object S is wetted, preventing foreign matter from adhering thereto, and the cleaning effect may be improved. Moreover, in the case where the floater fluid Fb is a liquid, the floater fluid Fb itself may clean the cleaning object S. In particular, while the cleaning apparatus 10 has the cleaning unit 12 configured to mainly clean the second surface Sb of the cleaning object S, by supplying the floater fluid Fb being a liquid to the first surface Sa of the cleaning object S, the first surface Sa may be benefited to be also cleaned to a certain extent.

The floater fluid Fb supplied in Step 103 or Step 106 may be a mixture (two fluids) of a liquid and a gas. In this case, the same effect may be achieved as the floater fluid Fb being a liquid.

As the control proceeds to Step 101, 104, or 106, to which the control proceeds through branches in Step 100 or Step 102 according to the respective conditions, the cleaning object S is supported by the supporting units 11 at the outer edge portion thereof as shown in FIGS. 2 and 3. In other words, Steps 101, 104, and 106 are the supporting step for supporting the cleaning object S with the supporting portions 14. In Step 101, the cleaning object S is in a state where the first surface Sa is in direct contact with the supporting surfaces 16 of the supporting units 11. In Step 104 or 106, the cleaning object S is in a state where the outer edge of the cleaning object S is elevated by the floater fluid Fb to be separated from the supporting surfaces 16.

Next, the control proceeds to Step 107. In Step 107, the rotational fluid Fa is supplied to the cleaning object S from the first supply ports 20, causing the cleaning object S to rotate on the supporting units 11 by the effect of the rotational fluid Fa. In other words, Step 107 is the rotating step for supplying the rotational fluid Fa from the first supply ports 20 to the cleaning object S and causing the cleaning object S supported by the supporting portions 14 to rotate. In the cleaning sequence, the cleaning object S is rotated by the rotational fluid Fa supplied from the supporting units 11. As such, a number of mechanically operable parts in the supporting units 11 is small, and the cleaning apparatus 10 may be provided in a compact and simple structure.

It is preferable that a liquid is the rotational fluid Fa to be supplied in Step 107. As in the case of the floater fluid Fb described above, by using a liquid as the rotational fluid Fa, the cleaning object S may be prevented from drying so that foreign material may be prevented from adhering to the cleaning object S, and the cleaning effect may be improved. Moreover, in the case where the rotational fluid Fa is a liquid, the rotational fluid Fa itself may clean the cleaning object S. In particular, while the cleaning apparatus 10 has the cleaning unit 12 located at the position for mainly cleaning the second surface Sb of the cleaning object S, a part of the rotational fluid Fa being a liquid may flow around the side surface Sc to the first surface Sa, and side surface Sc and the first surface Sa may be benefited to be also cleaned to a certain extent.

Optionally, the rotational fluid Fa to be supplied in Step 107 may be a mixture fluid (two fluids) containing a liquid and a gas. In this case, an effect substantially the same as the effect achievable with the rotational fluid Fa being a liquid may be achieved.

Once rotation of the cleaning object S is stabilized, the control proceeds to Step 108 to clean the cleaning object S. In other words, Step 108 is the cleaning step for cleaning the cleaning object S while the cleaning object S rotates. Cleaning of the cleaning object S in Step 108 may be performed using the cleaning unit 12 such that, as shown in FIG. 3, the cleaning unit 12 jets the cleaning water supplied from the cleaning-water supply source 27 downward from the cleaning nozzle 26 and cleans the cleaning object S with the cleaning water jetted from the cleaning nozzle 26. In the example shown in FIG. 3, the second surface Sb of the cleaning object S is the main target to be cleaned by the cleaning unit 12.

By the cleaning nozzle 26 being movable to the position above the outer edge of the cleaning object S, the cleaning water may be delivered also to the side surface Sc of the cleaning object S and a part of the first surface Sa continuous from the side surface Sc to clean.

The cleaning unit 12 jetting the cleaning water downward from the cleaning nozzle 26 located above the cleaning object S may apply moderate pressure, which may otherwise cause the cleaning object S to deviate upward from the supporting units 11, from above to the cleaning object S, thereby preventing the cleaning object S from being elevated excessively. Moreover, it is the cleaning water from the cleaning nozzle 26 that is supplied by the cleaning unit 12; therefore, the cleaning object S may not be pressed excessively intensely against the supporting surfaces 16 from above.

For example, unlike the cleaning unit 12 in the present embodiment, if the second surface Sb of the cleaning object S is cleaned while a tool such as a cleaning brush located above the cleaning object S is urged downward against the second surface Sb of the cleaning object S, resistance against the rotation of the cleaning object S caused by the rotational fluid Fa may increase, and a load to rotate the cleaning object S may increase too large so that it may not be negligible. Moreover, the elevating effect by the floater fluid Fb may be reduced, causing the cleaning object S to slidably rotate on the supporting surfaces 16, and the outer edge of the cleaning object S may be dirtied or damaged. In contrast, by cleaning the cleaning object S with the cleaning water supplied from the cleaning nozzle 26, such problems are unlikely to occur.

As described above, the cleaning object S may be cleaned using the rotational fluid Fa as the cleaning water supplied thereto in Step 107. In this case, as a first selection in the cleaning process in Step 108, the cleaning water jetted from the cleaning nozzle 26 and the rotational fluid Fa jetted from the first supply ports 20 may be used in combination for cleaning. As a second selection, without supplying cleaning water from the cleaning nozzle 26, the rotational fluid Fa supplied from the first supply ports 20 may be jetted as the cleaning water to clean the cleaning object S. In the case of the second selection, the cleaning unit 12 (the cleaning nozzle 26, the cleaning-water supply source 27, and the air supply source 28) may be omitted, and the supporting units 11 may serve to provide the cleaning function of the cleaning unit (the configuration to jet the rotational fluid Fa may serve as the cleaning unit).

In either the first selection or the second selection, the floater fluid Fb in addition to the rotational fluid Fa may be used as the cleaning water, optionally. By using both the rotational fluid Fa and the floater fluid Fb as the cleaning water, the cleaning effect may be improved even more.

As such, how the cleaning water may be supplied in the cleaning process in Step 108 may be selected from multiple options. The rotational fluid Fa has been supplied from the first supply ports 20 continuously from Step 107; therefore, in Step 108, the controller may merely need to select whether the cleaning water should be supplied from the cleaning nozzle 26 or not, in the configuration where the cleaning apparatus 10 is equipped with the cleaning nozzle 26. Therefore, complicated control is not required.

The cleaning process in Step 108 may be terminated on a predetermined time basis or may be ended based on a predetermined condition other than time. The condition other than time may include, for example, a degree of dirtiness removed from the cleaning object S, which may be determined by an amount of dirt contained in the cleaning water being collected or based on information indicating dirtiness of the cleaning object S estimated from, for example, a reflection rate in a captured image of the cleaning object S, so that the controller may continue the cleaning process until the controller determines that the dirtiness is removed from the cleaning object S.

After the cleaning process in Step 108 is completed, the control proceeds to Step 109. In Step 109, whether the rotational fluid Fa is to be supplied continuously or not is selected. For example, in the case where the rotational fluid Fa supplied in Step 107 through Step 108 is a liquid, if the rotational fluid Fa is continuously supplied, the liquid may hinder the cleaning object S from drying in the next drying sequence. Therefore, supply of the rotational fluid Fa may be discontinued. For another example, supply of the rotational fluid Fa may be discontinued uniformly regardless of the type of the rotational fluid Fa once the cleaning process is completed. In these cases, a negative determination NO is made in Step 109, and the control may proceed to S110, where supply of the rotational fluid Fa from the first supply ports 20 is discontinued, and thereafter proceed to Step 111.

As described above, it is preferable that the rotational fluid Fa to be supplied in Step 107 through Step 108 is a liquid. However, in a case where the rotational fluid Fa supplied in Step 107 through Step 108 is a gas, it may be determined that the gas does not hinder the cleaning object S from drying in the next drying sequence, and supply of the rotational fluid Fa may be continued during transition from the cleaning sequence to the drying sequence. In this case, a positive determination YES is made in Step 109, and the control may proceed directly to Step 111 without detouring to Step 110.

In Step 111, whether the floater fluid Fb is to be supplied continuously or not is selected. For example, in the case where the floater fluid Fb supplied in Step 103 or Step 106 is a liquid, if the floater fluid Fb is continuously supplied, the liquid may hinder the cleaning object S from drying in the next drying sequence. Therefore, supply of the floater fluid Fb may be discontinued. For another example, supply of the floater fluid Fb may be discontinued uniformly regardless of the type of the floater fluid Fb once the cleaning process is completed. In these cases, the controller may determine negatively NO in Step 111, and the control may proceed to S112, where supply of the floater fluid Fb from the second supply ports 23 is discontinued, and thereafter proceed to Step 113 (drying sequence) shown in FIG. 6.

As described above, it is preferable that the floater fluid Fb to be supplied in Step 103 or Step 106 is a liquid. However, in a case where the floater fluid Fb supplied in Step 103 or Step 106 is a gas, it may be determined that the gas does not hinder the cleaning object S from drying in the next drying sequence, and supply of the floater fluid Fb may be continued during transition from the cleaning sequence to the drying sequence. In this case, a positive determination YES is made in Step 111, and the control may proceed directly to Step 113 shown in FIG. 6 without detouring to Step 112.

In a case where the floater fluid Fb was not selected to be used in Step 100, the cleaning sequence has been executed without supplying the floater fluid Fb. Therefore, the control may skip Sep 111 and proceed to Step 113 (drying sequence) shown in FIG. 6.

### Drying Sequence

Next to the cleaning sequence, the control proceeds to the drying sequence shown in FIG. 6. Similarly to the cleaning sequence as described above, in the drying sequence, the cleaning apparatus 10 may select an option for drying between drying the cleaning object S in a state elevated by the floater fluid Fb and drying the cleaning object S in a state not being elevated by the floater fluid Fb. Drying the cleaning object S in the state not being elevated by the floater fluid Fb is performed by rotating the cleaning object S in a state where the outer edge of the first surface Sa is in contact with the supporting surfaces 16 of the supporting units 11.

In Step 113, the controller determines an operating condition of the cleaning apparatus 10 in the drying sequence. If the operating condition meets the condition for drying using the floater fluid Fb (YES in Step 113), the control proceeds to Step 114, where the controller starts supplying the floater fluid Fb from the second supply ports 23 to the cleaning object S. For the floater fluid Fb to be supplied in Step 114, a gas, rather than a liquid that may wet the cleaning object S, is selected. The control proceeds to Step 115 with supplying the floater fluid Fb to the cleaning object S from the second supply ports 23. With the floater fluid Fb being supplied, the cleaning object S may float from the supporting surfaces 16.

If the operating condition meets the condition for drying without using the floater fluid Fb (NO in Step 113), the control proceeds to Step 115 without supplying the floater fluid Fb to the cleaning object S from the second supply ports 23.

Optionally, in a case where the cleaning apparatus 10 is configured to supply solely a liquid of floater fluid Fb, a negative selection NO may be made automatically in Step 113.

In the case where the selection for supplying the floater fluid Fb continuously was made earlier in Step 111, the floater fluid Fb is being supplied currently (the cleaning object S is floating from the supporting surfaces 16 by the floater fluid Fb having been supplied). Therefore, the control may skip Sep 113 and proceed to Step 115.

In Step 115, the controller determines a supplying status (whether the rotational fluid Fa is being supplied or not being supplied) of the rotational fluid Fa. In a case where supply of the rotational fluid Fa was discontinued in Step 110, the rotational fluid Fa is not being supplied, and, a positive determination YES is made, in Step 115, and the control proceeds to Step 116, where the controller starts supplying the rotational fluid Fa to the cleaning object S from the first supply ports 20. For the rotational fluid Fa to be supplied in Step 116, a gas, rather than a liquid that may wet the cleaning object S, is selected. With the rotational fluid Fa being supplied, the cleaning object S may be rotated by the effect of the rotational fluid Fa. When the rotation of the cleaning object S is stabilized, the control proceeds to Step 117.

In the case where the selection for supplying of the rotational fluid Fa continuously was made earlier in Step 109, the rotational fluid Fa is being supplied currently, and the cleaning object S is being rotated by the effect of the rotational fluid Fa. Therefore, a negative determination NO is made in Step 115, and the control may proceed directly to Step 117 without detouring to Step 116.

Similarly to the cleaning sequence described earlier, in the drying sequence, the cleaning object S is rotated by the rotational fluid Fa supplied from the supporting units 11. Therefore, with a small number of mechanically operable parts, the cleaning apparatus 10 may be provided in a compact and simple structure.

In Step 117, the cleaning object S having been cleaned is dried. The cleaning object S may be dried in Step 117 with use of the cleaning unit 12. As shown in FIG. 3, the cleaning unit 12 jets the air supplied from the air supply source 28 downward through the cleaning nozzle 26 and dries the cleaning object S by the jetted air. In the exemplary configuration in FIG. 3, the second surface Sb of the cleaning object S may be the main target to be dried by the cleaning unit 12. Meanwhile, centrifugal force by the rotation of the cleaning object S may remove the liquid droplets from not only the second surface Sb but also the first surface Sa and the side surface Sc; therefore, the cleaning object S may be dried entirely.

By the cleaning nozzle 26 being movable to the position above the outer edge of the cleaning object S, the air from the cleaning nozzle 26 may be delivered not only to the second surface Sb but also to the side surface Sc of the cleaning object S and a part of the first surface Sa continuous from the side surface Sc to dry.

The cleaning unit 12 jets the air downward from the cleaning nozzle 26 located above the cleaning object S to apply moderate pressure from above to the cleaning object S, thereby preventing the cleaning object S, which may otherwise deviate upward from the supporting units 11, from being elevated excessively. Moreover, it is the air from the cleaning nozzle 26 that is supplied by the cleaning unit 12; therefore, the cleaning object S may not be pressed excessively intensely against the supporting surfaces 16 from above.

The cleaning object S may be dried using the rotational fluid Fa as the drying gas in the drying process in Step 117. In this case, as a first selection, for example, the air jetted from the cleaning nozzle 26 and the rotational fluid Fa jetted from the first supply ports 20 may be used in combination for drying. For another example, as a second selection, without supplying the air from the cleaning nozzle 26, the rotational fluid Fa supplied from the first supply ports 20 may be jetted as the air to dry the cleaning object S. In the case of the second selection, the cleaning unit 12 (the cleaning nozzle 26, the cleaning-water supply source 27, and the air supply source 28) may be omitted, and the supporting units 11 may serve to provide the dryer function of the cleaning unit (the configuration to jet the rotational fluid Fa may serve as the cleaning unit).

In either the first selection or the second selection, the floater fluid Fb in addition to the rotational fluid Fa may be used as the gas for drying, optionally. By using both the rotational fluid Fa and the floater fluid Fb as the dryer gas, the drying effect may be improved even more.

As such, how the drying gas may be supplied in the drying process in Step 117 may be selected from multiple options. The rotational fluid Fa has been from the first supply ports 20 continuously from Step 107 or Step 116; therefore, in Step 117, the controller may merely need to select whether the dryer air should be supplied from the cleaning nozzle 26 or not, in the case where the cleaning apparatus 10 is equipped with the cleaning nozzle 26. Therefore, a complicated control is not required.

The drying process in Step 117 may be terminated on a predetermined time basis or may be ended based on a predetermined condition other than time. The condition other than time may include, for example, a degree of dryness of the cleaning object, which may be determined based on information indicating dryness of the cleaning object S estimated from, for example, a reflection rate in a captured image of the cleaning object S, so that the controller may continue the drying process until the controller determines that the cleaning object S is substantially dry.

After the drying process in Step 117 is completed, the control proceeds to Step 118. In Step 118, supply of the rotational fluid Fa from the first supply ports 20 is discontinued. As supply of the rotational fluid Fa is discontinued, the cleaning object S stops rotating and stays to be supported on the supporting surfaces 16 of the supporting units 11.

Next, the controller determines a supplying status of the floater fluid Fb in Step 119. In a case where the drying process was performed without supplying the floater fluid Fb to the cleaning object S in Step 117, a negative determination NO is made in Step 119, and the control proceeds to Step 120. In Step 120, the cleaning object S supported by the supporting units 11 is picked up by the conveyer assembly and removed from the cleaning apparatus 10 by the conveyer assembly.

In a case where the drying process was performed with the floater fluid Fb being supplied to the cleaning object S to elevate the cleaning object S in Step 117, a positive determination YES is made in Step 119, and the control proceeds to Step 121. In Step 121, the controller determines a setting of timing when to remove the cleaning object S from the supporting units 11.

In a case where the cleaning object S is removed from the supporting units 11 after supply of the floater fluid Fb is discontinued (NO in Step 121), the control proceeds to Step 122, where supply of the floater fluid Fb from the second supply ports 23 is discontinued, and thereafter, in Step 123, the cleaning object S is removed by the conveyer assembly from the supporting units 11.

In a case where the cleaning object S is removed from the supporting units 11 before supply of the floater fluid Fb is discontinued (YES in Step 121), the control proceeds to Step 124, where the cleaning object S is removed by the conveyer assembly from the supporting units 11, and thereafter, in Step 125, supply of the floater fluid Fb from the second supply ports 23 is discontinued.

The supporting units 11 are configured to support the cleaning object S without covering the second surface Sb; therefore, in Step 123 or Step 124, the conveyer assembly may pick up and hold the cleaning object S by the second surface Sb to remove from the supporting units 11 regardless of whether the cleaning object S is elevated by the floater fluid Fb or not.

The drying sequence is completed by performing one of Step 120, 123, or 125. Once the drying sequence is completed, the control exits the flowchart shown in FIG. 6, and the series of operations in the cleaning apparatus 10 ends thereat.

As described above, according to the cleaning apparatus 10 of the first embodiment and the cleaning method using the cleaning apparatus 10, the cleaning object S is rotated by the rotational fluid Fa supplied from the first supply ports 20. Therefore, a complex mechanical structure, such as a supporting mechanism using a shaft to rotate the cleaning object S or a transmission mechanism to transmit power of a motor, is not required, and the cleaning apparatus 10 may be provided in a downsized and simple structure to clean the cleaning object S efficiently.

Moreover, the cleaning apparatus 10 may elevate the cleaning object S by the floater fluid Fb supplied from the second supply ports 23 so that the cleaning object S may be cleaned in the state not contacting the supporting units 11. Therefore, the cleaning object S may be rotated at a high speed by a low load. Moreover, the cleaning object S may be prevented from being dirtied or damaged by contact with the supporting units 11.

In particular, by starting to supply the floater fluid Fb to the supporting surfaces 16 of the supporting unit 11 before the cleaning object S is placed thereon, and by discontinuing the supply of the floater fluid Fb after the cleaning object S is separated from the supporting surfaces 16 of the supporting units 11 to be removed from the supporting units 11, the series of processes may be completed while the cleaning object S remains contactless throughout the processes.

The rotational fluid Fa and/or the floater fluid Fb may be used as complements to the functions of the cleaning water and for the dryer air to be supplied from the cleaning unit 12, thereby improving the efficiency of cleaning and drying. Moreover, optionally, the cleaning apparatus 10 may be configured such that the rotational fluid Fa or the floater fluid Fb may be used as the cleaning water or the dryer air (applying a structure to supply the rotational fluid Fa or the floater fluid Fb to function as the cleaning unit), without being equipped with the configuration of the cleaning unit 12. In the case where the cleaning object S is cleaned with the rotational fluid Fa, the cleaning unit may at least include the first supply ports 20 for supplying the rotational fluid Fa.

In the above description, the cleaning sequence in FIG. 5 and the drying sequence in FIG. 6 are performed consecutively; however, optionally, the cleaning sequence alone may be performed in the cleaning apparatus 10, and the drying sequence may be performed in an apparatus different from the cleaning apparatus 10, or the cleaning object S may be dried naturally.

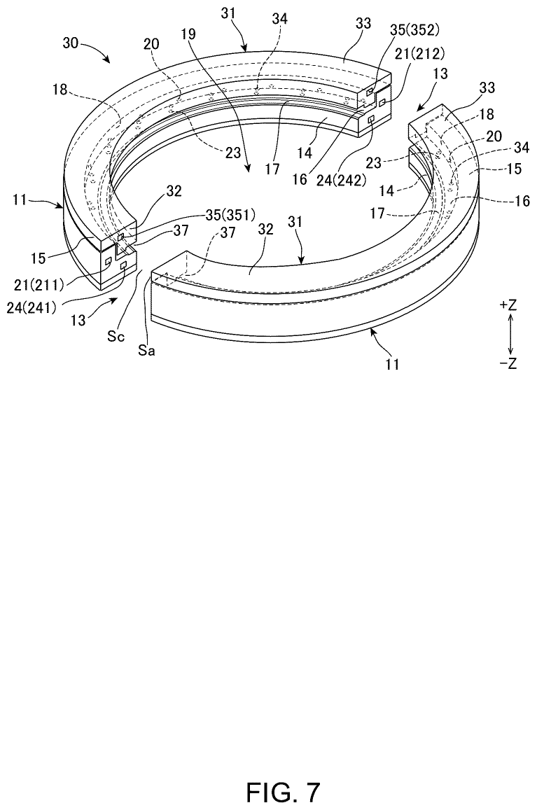

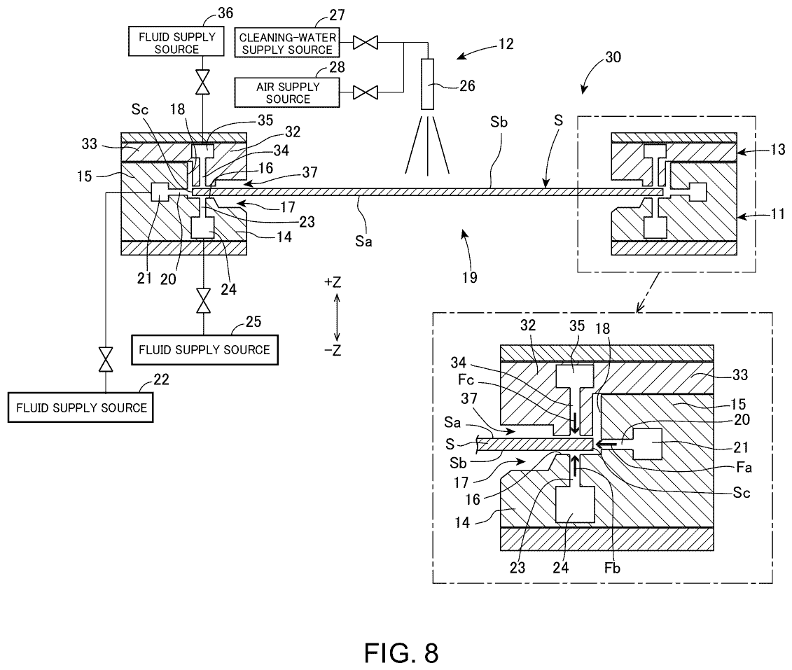

FIGS. 7 and 8 show a cleaning apparatus 30 according to a second embodiment. The cleaning apparatus 30 includes, further to the configuration of the cleaning apparatus 10 in the first embodiment, lids 31 arranged to face the outer edge on the second surface Sb of the cleaning object S. The configuration of the cleaning apparatus 30 is the same as that of the cleaning apparatus 10 except for the configuration of the lids 31; therefore, description of the configuration common to the cleaning apparatus 10 is herein omitted.

The lids 31 are in a form of a ring divided by the communicating portions 13 into two along the circumferential direction, similarly to the supporting units 11. The lids 31 each include an inner ring portion 32 located on an inner circumferential side and an outer ring portion 33 located on an outer circumferential side. The inner ring portion 32 and the outer ring portion 33 are formed integrally.

The outer ring portion 33 is supported on top of the side portion 15 of the supporting unit 11. The inner ring portion 32 has a greater thickness in the vertical direction than the outer ring portion 33 and is fitted to the step shape in the supporting unit 11 formed between the supporting surface 16 of the supporting portion 14 and the inner circumferential surface 18 of the side portion 15. As the lids 31 are attached from above to the supporting units 11 supporting the cleaning object S, as shown in FIG. 8, the inner ring portions 32 are located above the outer edge (area on the second surface Sb closer to the side surface Sc) of the cleaning object S. With the outer ring portions 33 being placed on the upper surfaces of the side portions 15, the inner ring portions 32 face the supporting portions 14 in the vertical direction with a predetermined amount of gap maintained there-between. As such, the inner ring portions 32 is prevented from contacting the cleaning object S, so that the rotation of the cleaning object S may not be hindered, or from covering the first supply ports 20, so that the jetting of the rotational fluid Fa may not be hindered.

In the inner ring portion 32 in each lid 31, a plurality of third supply ports 34 are formed to open downward. The plurality of third supply ports 34 are arranged at predetermined intervals in the circumferential direction of the lid 31 (in the rotating direction of the cleaning object S) at positions above the second supply ports 23 formed in the supporting portion 14 in the supporting unit 11. The plurality of third supply ports 34 in this arrangement are located to be open toward the second surface Sb of the cleaning object S at positions in the vicinity of the outer edge of the cleaning object S supported by the supporting units 11. The number of the plurality of second supply ports 23 and circumferential intervals thereof coincide with the number of the third supply ports 34 and the circumferential intervals thereof, and as shown in FIG. 8, the second supply ports 23 and the third supply ports 34 are respectively arranged coaxially and aligned vertically.

Inside each lid 31, a fluid supply path 35 extending in the circumferential direction is formed. The plurality of third supply ports 34 are formed to branch off from the fluid supply path 35 and extend downward. The third supply ports 34 each extend substantially vertically.

The cleaning apparatus 30 is provided with a fluid supply source 36 to supply the fluid to the fluid supply paths 35 and is connected to the fluid supply paths 35 via an open/close valve. The fluid to be supplied by the fluid supply source 36 is at least one of a liquid or a gas, preferably water, when the fluid is a liquid, or air, when the fluid is a gas. Optionally, depending on the material or the type of the cleaning object S, a fluid other than water or air may supplied from the fluid supply source 36.

In a case where the fluid supply source 36 is capable of supplying both a liquid and a gas, the fluid supply source 36 may be configured to have a liquid supply source and a gas supply source, and the type of the fluid to be supplied to the fluid supply paths 35 may be selected by an operation of an open/close valve in a flow path connecting to the liquid supply source and the gas supply source. Optionally, a mixed fluid (two fluids) containing both a liquid and a gas may be supplied from the fluid supply source 36.

On one of end faces of each lid 31 in the circumferential direction facing the communicating portion 13, an inlet 351, from which the fluid supplied from the fluid supply source 36 may be drawn into the fluid supply path 35, is formed, and on the other of the end faces of each lid 31 in the circumferential direction facing the communicating portion 13, an outlet 352, from which the fluid flowed through the fluid supply path 35 may be discharged, is formed.

The fluid supplied from the fluid supply source 36 to the inlet 351 of each fluid supply path 35 may travel inside the fluid supply path 35 in an arc shape in a plan view. The fluid flowing through the fluid supply paths 35 may enter the individual third supply ports 34 and may be jetted out from outlets formed on the lower surface of the inner ring portions 32.

The fluid jetted from the third supply port 34 will be herein called a hold-down fluid Fc. In FIG. 8, the hold-down fluid Fc is represented schematically in an arrow. The hold-down fluid Fc jetted from the third supply ports 34, which extend in the vertical direction, flows downward and hits the second surface Sb of the cleaning object S. When cleaning, as the cleaning object S is elevated by the floater fluid Fb jetted from the second supply ports 23, the hold-down fluid Fc jetted from the third supply ports 34 may hold down the cleaning object S from above, restricting the cleaning object S from floating excessively from the supporting portions 14 of the supporting units 11. As such, the cleaning object S may be held stably at a constant position in the vertical direction and rotated by the balance between the forces of the floater fluid Fb and the hold-down fluid Fc.

The flowing speed and the flowing rate of the floater fluid Fb are set depending on the pressure or the amount of the fluid to be supplied from the fluid supply source 25, and the flowing speed and the flowing rate of the hold-down fluid Fc are set depending on the pressure or the amount of the fluid to be supplied from the fluid supply source 36. Therefore, by the controller controlling the cleaning apparatus 30 and the behaviors of the fluid supply source 25 and the fluid supply source 36, the balance between the force of the floater fluid Fb to elevate the cleaning object S and the force of the hold-down fluid Fc to restrict the cleaning object S from floating may be adjusted, and the cleaning object S may be rotated in the elevated state between the supporting units 11 and the lids 31.

In order to prevent the cleaning object S from flapping or bending, it is preferable that the second supply ports 23 and the third supply ports 34 are located coaxially aligning in the vertical direction, as shown in FIG. 8, so that the positions where the floater fluid Fb hits the cleaning object S and the positions where the hold-down fluid Fc hits the cleaning object S are aligned. However, as long as the cleaning object S is elevated and rotated preferably between the supporting units 11 and the lids 31, the arrangement is not necessarily limited as above, or the positions of the second supply ports 23 and the third supply ports 34 in the circumferential direction may be offset from each other.

The inner ring portion 32 in each lid 31 has a discharging portion 37 in a form of a step located at a position higher than the positions of the openings of the third supply ports 34, on the inner circumferential side with respect to the area where the third supply ports 34 are formed. In other words, at a position on the inner circumferential side and adjacent to the third supply ports 34, the discharging portions 37 to form a larger gap with the cleaning object S than the third supply ports 34 are provided. With the lids 31 attached to the supporting units 11, the discharging portions 37 of the lids 31 are located to face toward the discharging portions 17 of the supporting units 11 in the vertical direction. Note that the discharging portions 37 are not required but are optional.

With this arrangement, the rotational fluid Fa, the floater fluid Fb, and the hold-down fluid Fc supplied to the areas in the vicinity of the outer edge of the cleaning object S may be easily discharged toward the area on the inner circumferential side of the lids 31 (the opening portion 19 in the supporting units 11) through the discharging portions 37. As such, the rotational fluid Fa, the floater fluid Fb, and the hold-down fluid Fc may be prevented from staying in the areas in the vicinity of the outer edge of the cleaning object S, and the cleaning object S may be stabilized in the posture and rotated accurately.

Cleaning operations and a method performed with the cleaning apparatus 30 configured as above are the same as those of the cleaning apparatus 10 described above except for the details concerning the lids 31; therefore, differences from the cleaning apparatus 10 will be briefly explained below with reference to the flowcharts shown in FIGS. 5 and 6.

After the cleaning object S is conveyed to the supporting units 11 and placed on the supporting surfaces 16 in the supporting step in one of Step 101, Step 104, or Step 106, the lids 31 are attached on top of the supporting units 11. The lids 31 are placed in a state such that the outer ring portions 33 are placed and supported on the upper surfaces of the side portions 15, and the inner ring portions 32 face the second surface Sb of the cleaning object S with a gap maintained there-between. Moreover, the lids 31 may be fixed to the supporting units 11 with fixing members (such as bolts and nuts or clamps), which are not shown.

In the cleaning sequence, in a case where the selection not to supply the floater fluid Fb from the second supply ports 23 is made in Step 100 (NO in Step 100), it is preferable that the hold-down fluid Fc may not be supplied to the cleaning object S from the third supply ports 34. Thereby, the cleaning object S may be prevented from being urged intensely against the supporting surfaces 16.

In a case where the selection to supply the floater fluid Fb is made in Step 100 (YES in Step 100), an option of supplying the hold-down fluid Fc from the third supply ports 34 or an option of not supplying the hold-down fluid Fc from the third supply ports 34 is selectable.

By supplying the hold-down fluid Fc from the third supply ports 34 to the cleaning object S in the cleaning sequence, the floater fluid Fb may elevate the cleaning object S while the hold-down fluid Fc holds the cleaning object S down so that the cleaning object S may be held at a constant height position and rotated stably.

In the case where the hold-down fluid Fc is not supplied from the third supply ports 34 in the cleaning sequence, the lids 31 may serve as physical lids, by which the cleaning object S may be prevented from deviating largely upward from the supporting units 11.

In the case where the hold-down fluid Fc is supplied from the third supply ports 34 in the cleaning sequence, in order to prevent the cleaning object S from adherence of foreign matter thereto due to dryness, it is preferable that the hold-down fluid Fc is a liquid (or two fluids). However, in a case where a gas is used as the floater fluid Fb in the cleaning sequence, use of a gas as the hold-down fluid Fc to match with the use of the floater fluid Fb being a gas is not necessarily excluded.

In Step 111 after cleaning in Step 108, further to the selection whether supplying of the floater fluid Fb is to be continued or discontinued, a selection whether supplying of the hold-down fluid Fc is to be continued or discontinued is made. Conditions for whether to continue or discontinue supplying of the hold-down fluid Fc are the same as those in the case of the floater fluid Fb described above. When supplying of the hold-down fluid Fc is to be discontinued, the process to discontinue supplying of the hold-down fluid Fc is performed in the same manner as the process to discontinue supplying of the floater fluid Fb in Step 112.

In the drying sequence, in a case where the selection not to supply the floater fluid Fb from the second supply ports 23 is made in Step 113 (NO in Step 113), it is preferable that the hold-down fluid Fc may not be supplied to the cleaning object S from the third supply ports 34. Thereby, the cleaning object S may be prevented from being urged intensely against the supporting surfaces 16.

In a case where the selection to supply the floater fluid Fb is made in Step 113 (YES in Step 113), an option of supplying the hold-down fluid Fc from the third supply ports 34 or an option of not supplying the hold-down fluid Fc from the third supply ports 34 is selectable.

By supplying the hold-down fluid Fc from the third supply ports 34 to the cleaning object S in the drying sequence, the floater fluid Fb may elevate the cleaning object S while the hold-down fluid Fc holds the cleaning object S down so that the cleaning object S may be held at a constant height position and rotated stably.

In the case where the hold-down fluid Fc is not supplied from the third supply ports 34 in the drying sequence, the lids 31 may serve as physical lids, by which the cleaning object S may be prevented from deviating largely upward from the supporting units 11.

In the case where the hold-down fluid Fc is supplied in the drying sequence, a gas, rather than liquid that may wet the cleaning object S, is selected as the hold-down fluid Fc.

After the drying process in Step 117 is completed and, in Step 118, supply of the rotational fluid Fa from the first supply ports 20 is discontinued, and after the cleaning object S stops rotating, the lids 31 are removed from the supporting units 11. In a case where the hold-down fluid Fc was being supplied continuously in the drying sequence, the lids 31 are removed from the supporting units 11 after supply of the hold-down fluid Fc is discontinued. By removing the lids 31, the inner ring portions 32 of the lids 31 no longer cover the cleaning object S from above. Therefore, the cleaning object S may be removed from the supporting units 11 by performing Step 119 and subsequent processes after the lids 31 are removed.

As described above, according to the cleaning operation and the cleaning method using the cleaning apparatus 30 of the second embodiment, which is provided with the lids 31 to cover the cleaning object S from above and is configured to hold the cleaning object S down by the hold-down fluid Fc jetted from the third supply ports 34 in the lids 31, the cleaning object S may be cleaned and dried while being securely supported by the supporting units 11 without deviating therefrom.

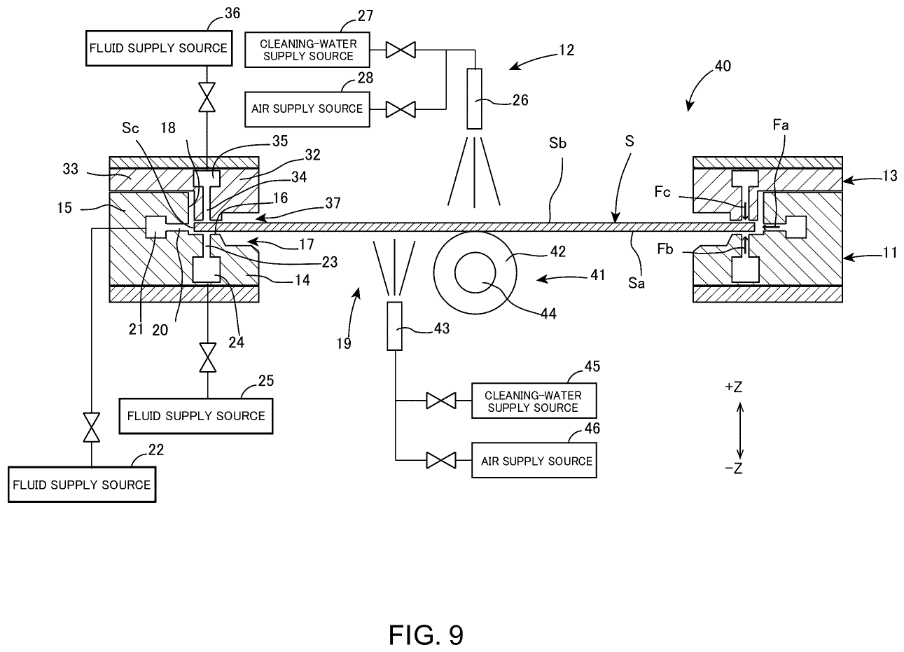

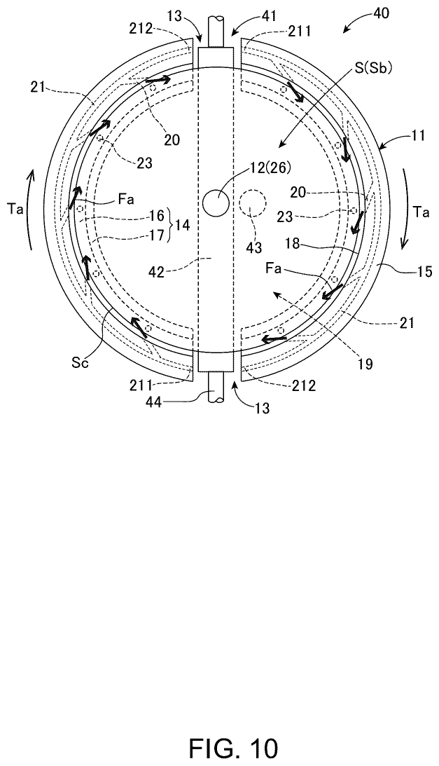

FIGS. 9 and 10 show a cleaning apparatus 40 according to a third embodiment. The cleaning apparatus 40 includes, further to the configuration of the cleaning apparatus 30 in the second embodiment, a second cleaning unit 41 configured to clean the first surface Sa of the cleaning object S. In other words, the cleaning apparatus 40 is configured to clean both the first surface Sa and the second surface Sb simultaneously by the cleaning unit 12 and the second cleaning unit 41, which are arranged above and below the cleaning object S, respectively. The configuration of the cleaning apparatus 40 is the same as that of the cleaning apparatus 30 except for the configuration of the second cleaning unit 41; therefore, description of the configuration common to the cleaning apparatus 30 is herein omitted. Note that in FIG. 10, the cleaning apparatus 40 is illustrated with the lids 31 being removed, and the illustration of the lids 31 is omitted.

The second cleaning unit 41 has a contact-cleaning device 42 and a cleaning nozzle 43 that are located below the cleaning object S being supported by the supporting units 11. The contact-cleaning device 42 includes a cylindrical body formed of, for example, a sponge or a brush and is supported rotatably around a horizontally extending supporting shaft 44. As shown in FIG. 10, the contact-cleaning device 42 and the supporting shaft 44 are arranged through the opening portion 19 in the supporting units 11, with both ends of the contact-cleaning device 42 being located in the communicating portions 13.

A cleaning-water supply source 45 and an air supply source 46 are connected to the cleaning nozzle 43 via respective open/close valves. The cleaning nozzle 43 may jet cleaning water supplied from the cleaning-water supply source 45, air supplied from the air supply source 46, or a mixed fluid containing cleaning water and air (two fluids) upward.

The contact-cleaning device 42 and cleaning nozzle 43 in the second cleaning unit 41 are cleaning devices that may be located at positions to face the first surface Sa of the cleaning object S which is supported by the supporting units 11. For cleaning the cleaning object S, cleaning water may be jetted from the cleaning nozzle 43 at the cleaning object S, and the contact-cleaning device 42 may contact the cleaning object S, thereby the first surface Sa of the cleaning object S may be cleaned. Optionally, the second cleaning unit 41 may be configured such that the contact-cleaning device 42 is rotatable passively by a frictional force generated between the contact-cleaning device 42 and the cleaning object S rotated by the rotational fluid Fa or such that the contact-cleaning device 42 is driven to rotate by a driving force transmitted to the supporting shaft 44 from, for example, a motor.

The contact-cleaning device 42 may contact the first surface Sa of the cleaning object S with appropriate contact pressure that may not cause an excessive friction force so as not to impede smooth rotation of the cleaning object S by the rotational fluid Fa. In order to adjust the contact pressure of the contact-cleaning device 42 against the cleaning object S, the supporting shaft 44 may be configured to be movable in the vertical direction, and the controller may preferably change the vertical position of the contact-cleaning device 42.

As shown in FIG. 10, a length of the contact-cleaning device 42 in an axial direction is greater than the diameter of the cleaning object S, and the contact-cleaning apparatus 42 is located to traverse the cleaning object S through the center in a direction of the diameter of the cleaning object S in a plan view. As such, by rotating the cleaning object S relatively to the supporting units 11, a cleaning range of the contact-cleaning apparatus 42 may entirely cover the first surface Sa.

The ends of the contact-cleaning apparatus 42 are both located in the spaces of the communicating portions 13. This allows the contact-cleaning apparatus 42, which is longer than the diameter of the cleaning object S and capable of cleaning the entire surface of the first surface Sa, to be arranged in the supporting units 11 without interfering therewith. As such, by using the spaces of the communicating portions 13, which are for discharging the fluid outward from the opening portion 19 in the supporting units 11, as spaces to accommodate the ends of the contact-cleaning apparatus 42, a structure with preferable space efficiency is provided. As the contact-cleaning apparatus 42 is located to be lower than the lids 31, the lids 31 may not interfere with the contact-cleaning apparatus 42, even if, for example, the lids 31 are in a form not divided by the communicating portions 13. In other words, in the light of prevention of interference with the contact-cleaning apparatus 42, it is sufficient that at least the supporting units 11 have the communicating portions 13.

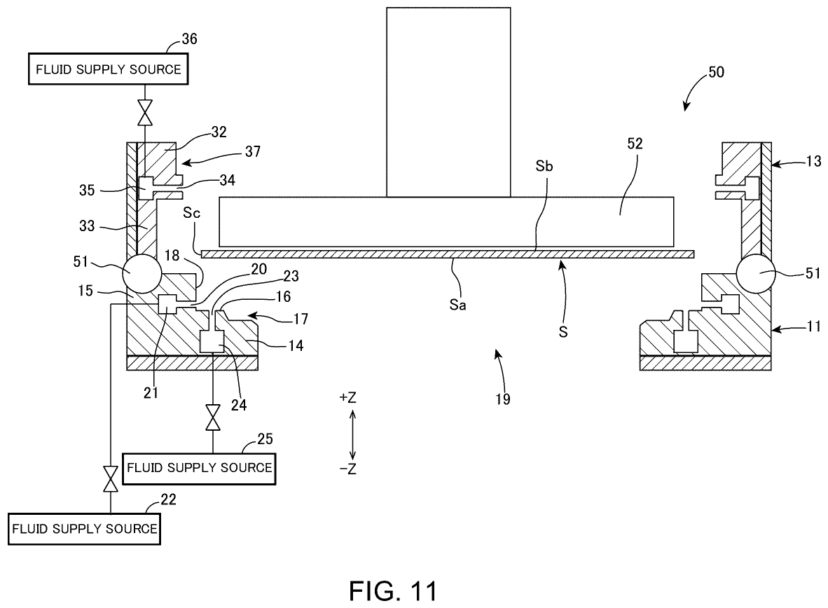

FIG. 11 shows a cleaning apparatus 50 according to a fourth embodiment. The cleaning apparatus 50 is based on the configuration of the cleaning apparatus 30 according to the second embodiment but is different in that the lids 31 are openable/closable with respect to the supporting units 11 via rotating assemblies 51. The lids 31 are in a configuration, as those in FIG. 7, divided in the circumferential direction by the communication portions 13 into two parts. Each of the lids 31 is pivotable to be opened or closed with respect to the supporting unit 11 via the respective rotating assembly 51.

The rotating assemblies 51 each support the lid 31 pivotably about an axis extending in the horizontal direction, and the lids 31 are pivoted by a driving force of, for example, a rotary cylinder or a motor. The lids 31, when at a closed position, cover the outer edge of the cleaning object S supported by the supporting units 11.

As the rotating assemblies 51 are driven to open the lids 31 upward, as shown in FIG. 11, the lids 31 uncover the areas above the outer edge of the cleaning object S supported by the supporting units 11, and the supporting units 11 may be loaded or unloaded with the cleaning object S using the conveyer assembly including, for example, a conveyer arm 52 that may suction and hold the second surface Sb of the cleaning object S. The conveyer arm 52 may be of a type that jets air from a holder surface (lower surface) and suctions to hold the cleaning object S in a contactless manner using the suctioning effect according to Bernoulli's theorem, or of a type that suctions to hold the cleaning object S by suctioning the air from suction holes formed in the holder surface (lower surface). By using the contactless-typed conveyer arm 52 and supporting the cleaning object S in the contactless manner using the floater fluid Fb in the cleaning apparatus 50, the cleaning object S may be handled in every stage in the process including loading and unloading without mechanically contacting the cleaning object S.

When the cleaning apparatus 50 is loaded or unloaded with the cleaning object S, the cleaning unit 12 is operated to withdraw the cleaning nozzle 26 from the position above the opening portion 19 in the supporting units 11 so that cleaning nozzle 26 may not interfere with the conveyer arm 52. FIG. 11 shows the cleaning nozzle 26 being withdrawn.

According to the cleaning apparatus 50, it is not necessary to attach or detach the lids 31 each time the cleaning apparatus 50 is loaded or unloaded with the cleaning object S. Therefore, while taking the advantage of the lids 31 when the cleaning object S is being cleaned, the process may be speeded up in the preparatory stage for cleaning and the post-cleaning stage so that the operation of the apparatus may be streamlined.

In the embodiments described above, the lids 31 are in the form divided in the circumferential direction into two pieces. However, optionally, the lids 31 may be configured as a lid 31 formed of a not divided single piece pivotably supported by a single rotating assembly 51 or as lids 31 divided in the circumferential direction into three or more pieces pivotably supported by three or more rotating assemblies 51.

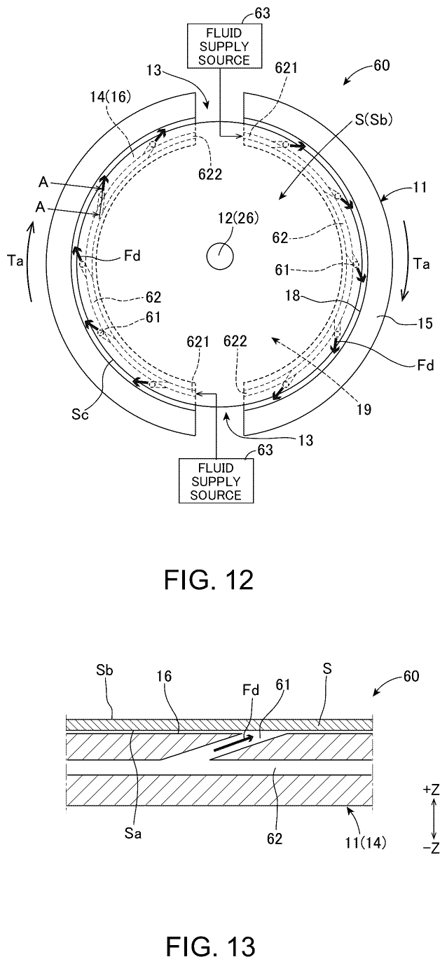

FIGS. 12 and 13 show a cleaning apparatus 60 according to a fifth embodiment. In the first through fourth embodiments, the cleaning object S is rotated by the rotational fluid Fa jetted from the first supply ports 20 formed on the inner circumferential surfaces 18 of the side portions 15 of the supporting units 11. In contrast, in the cleaning apparatus 60, the cleaning object S is rotated by a rotational fluid Fd jetted from a plurality of first supply ports 61, which are formed in the supporting portions 14 of the supporting units 11 and are open on the supporting surfaces 16.

The plurality of first supply ports 61 are arranged at predetermined intervals in the circumferential direction of the supporting units 11 (in the rotating direction of the cleaning object S), and the outlets of the first supply ports 61 are located in the vicinity of the outer edge of the cleaning object S supported by the supporting units 11 and are open toward the first surface Sa of the cleaning object S.

Inside the supporting portion 14 in each supporting unit 11, a fluid supply path 62 extending in the circumferential direction is formed. The fluid supply paths 62 forms an annular flow path located on the inner side in the circumferential direction with respect to the inner circumferential surface 18 of the side portion 15, having an arc form. A plurality of first supply ports 61, which are flow paths branching off from the fluid supply path 62 and extend obliquely upward to the supporting surface 16, are formed at predetermined intervals in the circumferential direction.

The cleaning apparatus 60 is provided with a fluid supply source 63 to supply the fluid to the fluid supply paths 62 and is connected to the fluid supply paths 64 via an open/close valve. The fluid supply source 63 includes a tank to store the fluid and a pump to pump the fluid from the tank. The fluid to be supplied by the fluid supply source 63 is at least one of a liquid or a gas, preferably water, when the fluid is a liquid, or air, when the fluid is a gas. Optionally, depending on the material or the type of the cleaning object S, a fluid other than water or air may supplied from the fluid supply source 63.

On one of the end faces of each supporting unit 11 in the circumferential direction facing the communicating portion 13, an inlet 621, from which the fluid supplied from the fluid supply source 63 may be drawn into the fluid supply path 62, is formed, and on the other of the end faces of each supporting unit 11 in the circumferential direction facing the communicating portion 13, an outlet 622, from which the fluid flowed through the fluid supply path 62 may be discharged, is formed.

The fluid supplied from the fluid supply source 63 to the inlet 621 of each fluid supply path 62 may travel inside the fluid supply path 62 in the arc shape in the plan view. The fluid flowing through the fluid supply paths 62 may enter the individual first supply ports 61 and may be jetted out from outlets of the first supply ports 61 formed on the supporting surfaces 16.

The fluid jetted from the first supply ports 61 will be herein called a rotational fluid Fd. As shown in FIG. 13, each of the plurality of first supply ports 61 is a flow path branching off from the fluid supply path 62 and extending obliquely upward to the supporting surface 16. In other words, each of the first supply ports 61 includes a flow path in a shape which includes a component (not parallel to the thickness direction of the cleaning object S) of the rotating direction of the cleaning object S supported by the supporting unit 11. The rotational fluid Fd jetted along the shape of each first supply port 61 is oriented in a direction including the component of the rotating direction of the cleaning object S and may contact the first surface Sa from an obliquely lower position. Therefore, the rotational fluid Fd may hit the first surface Sa in the vicinity of the outer edge of the cleaning object S so that the force in the rotating direction acts on the cleaning object S, and the cleaning object S supported by the supporting units 11 may be rotated by the force of the rotational fluid Fd.

When the amount and the force of the fluid to be supplied are equal, the configurations of the cleaning apparatuses 10, 30, 40, 50 of the first through fourth embodiments, which use the rotational fluid Fa jetted from the first supply ports 20 located on the exterior of the side surface Sc of the cleaning object S, may transmit the force in the rotating direction to cleaning object S more efficiently than the configuration of the cleaning apparatus 60 according to the fifth embodiment, which uses the rotational fluid Fd jetted from the first supply ports 61 toward the first surface Sa of the cleaning object S. Therefore, in the cleaning apparatus 60, the amount and the speed of the flow and/or the type of the rotational fluid Fd are adjusted in consideration of the positions of the first supply ports 61 so that the rotating force in sufficient intensity may be applied to the cleaning object S.

For example, by using a liquid having a higher viscosity than a gas as the rotational fluid Fd, a substantial rotating force may be applied to the cleaning object S. Moreover, the rotational fluid Fd being a liquid may have the effect of elevating the cleaning object S from the supporting surfaces 16 so that the rotational fluid Fd may work also as the floater fluid Fb.

On the other hand, in a case where a gas is used as the rotational fluid Fd, if the speed of the rotational fluid Fd flowing along the first surface Sa is high, a negative pressure may be generated between the supporting surfaces 16 and the first surface Sa by Bernoulli's theorem, and the cleaning object S may be rotated while being attracted to (but without contacting) the supporting surfaces 16. In this case, floating of the cleaning object S may be regulated without using the hold-down fluid Fc described earlier.

Unlike the cleaning apparatus 60 of the present embodiment, optionally, the cleaning object S may be rotated by jetting a rotational fluid toward the second surface Sb rather than the first surface Sa of the cleaning object S. For example, the lids 31 described above may be added to the cleaning apparatus 50, and the first supply ports 61 to replace the third supply ports 34 may be formed in the lids 31. Thereby, the rotational fluid that may work similarly to the rotational fluid Fd may be jetted at the second surface Sb.

As shown in FIG. 12, the rotational fluid Fd jetted from the first supply ports 61 contains not only a component to flow in the rotating direction of the cleaning object S but also a component to proceed toward the outer circumferential side of the cleaning object S in a plan view. In other words, the first supply ports 61 are each in a form with inclination, so as to expand toward the outer circumferential side of the supporting units 11, with respect to a tangent to the flowing direction Ta of the fluid flowing in the fluid supply path 62.

When the rotational fluid Fd is jetted at the first surface Sa of the cleaning object S, and if the fluid (in particular, air) concentrates at a center on the first surface Sa, the flow may collide with air currents in the surrounding area and stagnate thereat, causing positive pressure in the area below the center of the first surface Sa. As the positive pressure grows in the area below the center of the first surface Sa, the cleaning object S may rapidly move in the direction to separate from the supporting surfaces 16 and may deviate from the state being supported by the supporting units 11.

In contrast, the structure of the first supply ports 61 described above may release the rotational fluid Fd toward the outer circumferential side of the cleaning object S effectively, preventing the rotational fluid Fd jetted from the first supply ports 61 from concentrating at the center of the cleaning object S, thereby enabling the cleaning object S to stay supported by the supporting units 11 stably.

The cleaning apparatus 60 shown in the drawings illustrates a case where the cleaning object S is rotated by the rotational fluid Fd supplied from the first supply ports 61 alone in the supporting portions 14. Optionally, however, the first supply ports 20 may be formed in the side portions 15 to supply the rotational fluid Fa described above, and the cleaning object S may be rotated by the rotational fluid Fd in combination with the rotational fluid Fa.

In the case where the cleaning object S is rotated by the rotational fluid Fd supplied from the first supply ports 61 alone, optionally, a configuration of the supporting units 11 with no side portions 15 may be applicable. In this case, however, the position of the cleaning object S in the horizontal direction may not be stabilized by the supporting portions 14 alone. Therefore, in order to prevent the cleaning object S from deviating in the horizontal direction, it is preferable that the side portions 15 are provided.

Optionally, the rotational fluid Fd may be used for cleaning the cleaning object S. In this arrangement, the cleaning unit to clean the cleaning object S incudes at least the first supply ports 61 for supplying the rotational fluid Fd.

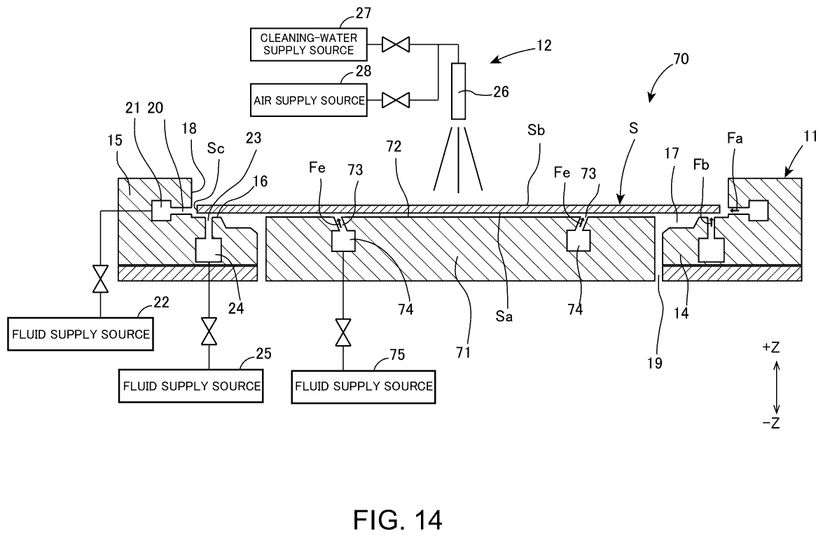

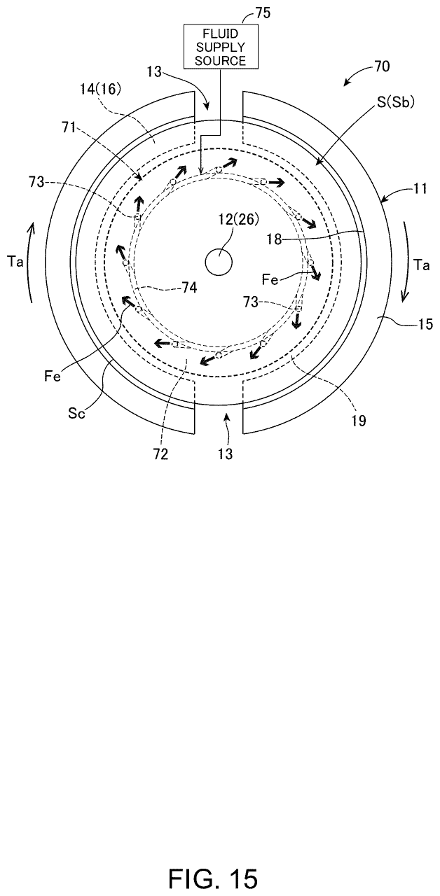

FIGS. 14 and 15 show a cleaning apparatus 70 according to a sixth embodiment. The cleaning apparatus 70 includes a disk-shaped central supporting unit 71 in the opening portion 19 of the supporting units 11. The central supporting unit 71 has a supporting surface 72 facing upward, on which the central portion of the first surface Sa of the cleaning object S may be supported. A height of the supporting surface 72 of the central supporting unit 71 is set at a height position, which is the height same as or higher than the supporting surfaces 16 of the supporting units 11.

In the cleaning apparatus 70, a rotational fluid Fe may be jetted at the cleaning object S from a plurality of first supply ports 73, which are open on the supporting surface 72 of the central supporting unit 71, to rotate the cleaning object S. The plurality of first supply ports 73 are formed at predetermined intervals in a circumferential direction (in the rotating direction of the cleaning object S) of the central supporting unit 71, and outlets of the first supply port 73 are located to be open toward the first surface Sa of the cleaning object S supported on the central supporting unit 71.

Inside the central supporting unit 71, a fluid supply path 74 extending in the circumferential direction is formed. The plurality of first supply ports 73, which are flow paths branching off from the fluid supply path 74 and extending obliquely upward toward the supporting surface 72, are formed at predetermined intervals in the circumferential direction. Note that the central supporting unit 71 is not in a ring shape; therefore, the fluid supply path 74 extending therein is not necessarily in a form of an arc extending in the circumferential direction of the central supporting unit 71.

The cleaning apparatus 70 is provided with a fluid supply source 75 to supply the fluid to the fluid supply path 74 and is connected to the fluid supply path 74 via an open/close valve. The fluid supply source 75 includes a tank to store the fluid and a pump to pump the fluid from the tank. The fluid to be supplied by the fluid supply source 75 is at least one of a liquid or a gas.

The fluid supplied from the fluid supply source 75 to the fluid supply path 74 may travel inside the fluid supply path 74 in the arc shape in a plan view in the flowing direction Ta (see FIG. 15). The fluid flowing through the fluid supply path 74 may enter the individual first supply ports 73 and may be jetted out from the outlets of the first supply ports 73 formed on the supporting surface 72 of the central supporting unit 71.

The fluid jetted from the first supply ports 73 will be herein called a rotational fluid Fe. Similarly to the first supply ports 61 (see FIG. 13) in the fifth embodiment, each of the plurality of first supply ports 73 is a flow path branching off from the fluid supply path 74 and extending obliquely upward to the supporting surface 72. In other words, the first supply ports 73 has a flow path in a shape including a component (not parallel to the thickness direction of the cleaning object S) of the rotating direction of the cleaning object S supported by the central supporting unit 71. The rotational fluid Fe jetted along the shape of each first supply port 73 is oriented in a direction including the component of the rotating direction of the cleaning object S and may contact the first surface Sa from an obliquely lower position. Therefore, the force in the rotating direction acts on the cleaning object S, and the cleaning object S supported by the central supporting unit 71 may be rotated by the force of the rotational fluid Fe.

Optionally, the rotational fluid Fe may be used for cleaning the cleaning object S. In this arrangement, the cleaning unit to clean the cleaning object S incudes at least the first supply ports 73 for supplying the rotational fluid Fe.

By using a liquid having a higher viscosity than a gas as the rotational fluid Fe, the effect to elevate the cleaning object S from the supporting surface 72 is achieved from the rotational fluid Fe while the rotational fluid Fe rotates the cleaning object S. Moreover, using a gas with a higher flow speed flowing along the first surface Sa as the rotational fluid Fe, by Bernoulli's theorem, the cleaning object S may be rotated while being attracted to the supporting surface 72.

According to the configuration in which the rotational fluid Fe is jetted from the central supporting unit 71, the rotational fluid Fe may be supplied to the cleaning object S without considering the shape of the outer edge of the cleaning object S for applying the rotating force to the cleaning object S; therefore, a cleaning object having a shape other than the disk shape such as the illustrated cleaning object S may be selected to be used in the cleaning apparatus 70. For example, a rectangular package substrate may be used as the cleaning object to be rotated.

As shown in FIG. 15, the first supply ports 73 are each in a form with inclination, so as to expand toward the outer circumferential side of the central supporting unit 71, with respect to a tangent to the flowing direction Ta of the fluid flowing through the fluid supply path 74. As such, the rotational fluid Fe jetted from the first supply ports 73 contains not only a component to flow in the rotating direction of the cleaning object S but also a component to proceed toward the outer circumferential side of the cleaning object S in a plan view. This structure of the first supply ports 73 may release the rotational fluid Fe toward the outer circumferential side of the cleaning object S effectively, preventing the rotational fluid Fe jetted from the first supply ports 73 from concentrating at the center of the cleaning object S, thereby enabling the cleaning object S to stay supported by the central supporting unit 71 stably.

According to the cleaning apparatus 70 shown in FIGS. 14 and 15, the ring-shaped supporting units 11 are located on the outer side of the central supporting unit 71. Further to the rotational fluid Fe to be supplied from the plurality of first supply ports 73 formed in the central supporting unit 71, optionally, the rotational fluid Fa to be jetted from the first supply ports 20 formed in the supporting units 11 and/or the floater fluid Fb to be jetted from the plurality of second supply ports 23 may be used in combination for supporting and rotating the cleaning object S.

Moreover, unlike the cleaning apparatus 70 shown in FIGS. 14 and 15, without providing the supporting units 11, the disk-shaped central supporting unit 71 alone may be provided as the supporting structure in the cleaning apparatus. In this case, however, the position of the cleaning object S in the horizontal direction may not be stabilized by the central supporting unit 71 alone. Therefore, in order to prevent the cleaning object S from deviating in the horizontal direction, it is preferable that a configuration equivalent to the side portions 15 are provided.

As described above, according to the cleaning apparatuses and the cleaning method in the above embodiments, the cleaning object may be rotated by supplying the fluid, thereby enabling cleaning of the cleaning object efficiently in a downsized structure without requiring a complex rotating mechanism.

The technique to rotate a cleaning object with use of a fluid may be applied to a processing operation other than cleaning as described in the above embodiments. For example, the technique may be applied to a spin-coating process, in which a liquid resin is supplied to a surface of a plate-shaped object, and the object is rotated to cause the liquid resin to spread on the surface thereof by the centrifugal force.

Embodiment of the present disclosure may not necessarily be limited to the configurations described above or in the modified examples but may be modified, substituted, or altered in various ways without departing from the spirit of the technical idea of the present disclosure. Furthermore, if the technical idea of the present disclosure may be realized in a different way due to technological progress or other derived technology, it may be implemented with use of the method. Therefore, the claims cover all embodiments that may be included within the scope of the technical idea of the present disclosure.

As explained above, according to the cleaning apparatuses and the cleaning method of the present disclosure, a cleaning object may be rotated and cleaned by a rotational fluid. Therefore, the cleaning object may be cleaned efficiently by a cleaning apparatus in a downsized structure, and a cost for introducing the cleaning apparatus and restrictions on an installation location may be reduced.

What is claimed is:

1. A cleaning apparatus including a cleaning unit configured to clean a cleaning object, comprising:
a supporting portion located on a side of a first surface of the cleaning object, the supporting portion being configured to support the cleaning object; and
at least one first supply port, from which a rotational fluid is supplied to the cleaning object supported by the supporting portion,
wherein the cleaning apparatus is configured to clean the cleaning object while the cleaning object is rotated by the rotational fluid supplied from the at least one first supply port.

2. The cleaning apparatus according to claim 1,
wherein the supporting portion is configured to support an outer edge of the cleaning object and includes a side portion configured to cover an exterior of the cleaning object supported by the supporting portion.

3. The cleaning apparatus according to claim 2,
wherein the at least one first supply port is formed on an inner circumference of the side portion.

4. The cleaning apparatus according to claim 3, further comprising:
at least one second supply port provided on a supporting surface of the supporting portion, the supporting surface being configured to support the cleaning object thereon,
wherein the cleaning unit is configured to clean the cleaning object in a state where the cleaning object is elevated from the supporting surface by a floater fluid supplied from the at least one second supply port.

5. The cleaning apparatus according to claim 1,
wherein the cleaning unit is configured to clean at least one of the first surface, a second surface opposite to the first surface, or a side surface, of the cleaning object.

6. The cleaning apparatus according to claim 1,
wherein the cleaning unit at least includes the at least one first supply port and is configured to clean the cleaning object with the rotational fluid.

7. The cleaning apparatus according to claim 1,
wherein the cleaning unit includes, separately from the at least one first supply port, a cleaning device locatable at a position to face at least one of the first surface of the cleaning object supported by the supporting portion or a second surface opposite to the first surface of the cleaning object, and the cleaning unit is configured to clean the cleaning object using the cleaning device.

8. The cleaning apparatus according to claim 1, further comprising a lid configured to be arranged to face a second surface opposite to the first surface of the cleaning object.

9. The cleaning apparatus according to claim 8, further comprising at least one third supply port, through which a fluid is supplied to the cleaning object, on a surface of the lid that faces the cleaning object.

10. A method for cleaning the cleaning object in the cleaning apparatus according to claim 1, comprising:
a supporting step including supporting the cleaning object with the supporting portion;
a rotating step including supplying the rotational fluid from the at least one first supply port to the cleaning object and causing the cleaning object supported by the supporting portion to rotate; and
a cleaning step including cleaning the cleaning object while the cleaning object rotates.
